(19) United States
(12) Patent Application Publication
(10) Pub. No.: US 2025/0351672 A1
(43) Pub. Date: Nov. 13, 2025

(54) DISPLAY DEVICE

(71) Applicant: Samsung Display Co., LTD., Yongin-si (KR)

(72) Inventors: Ki Won KIM, Yongin-si (KR); Jong In KIM, Yongin-si (KR); Kap Soo YOON, Yongin-si (KR); Do Hyun JUNG, Yongin-si (KR); Hyun Seong KANG, Yongin-si (KR)

(21) Appl. No.: 19/040,092

(22) Filed: Jan. 29, 2025

(30) Foreign Application Priority Data
May 9, 2024 (KR) 10-2024-0061164

(51) Int. Cl. H10K 59/121; G09G 3/3233; H10K 59/131

(52) U.S. Cl. CPC H10K 59/1213; G09G 3/3233; H10K 59/131; G09G 2300/0426; G09G 2300/0465; G09G 2300/0819; G09G 2300/0842

(57) ABSTRACT

A display device includes, a light emitting element including a first electrode, a light emitting layer, and a second electrode, a first transistor including a first source electrode, a first active area, a first drain electrode, and a first gate electrode, a second transistor including a second source electrode, a second active area, a second drain electrode, and a second gate electrode, and a third transistor including a third source electrode, a third active area, a third drain electrode, and a third gate electrode, wherein the first source electrode is connected to the first electrode, the second source electrode is connected to the first gate electrode, the third drain electrode is connected to the first source electrode, the second gate electrode and the third gate electrode are defined by a same conductive line, and the second active area and the third active area are disposed in different layers.

This application claims priority to Korean Patent Application No. 10-2024-0061164, filed on May 9, 2024, and all the benefits accruing therefrom under 35 U.S.C. § 119, the content of which in its entirety is herein incorporated by reference.

### BACKGROUND

### 1. Field

Embodiments of the disclosure relate to a display device.

### 2. Description of the Related Art

The importance of display devices is gradually increasing with the development of multimedia. In Accordingly, various display devices such as a liquid crystal display device (LCD) and an organic light emitting diode display device (OLED) have been developed.

Among the display devices, a self-light emitting display device includes a self-light emitting element, for example, an organic light emitting element. The self-light emitting element may include two opposing electrodes and a light emitting layer interposed therebetween. In a case where the self-light emitting element is the organic light emitting element, electrons and holes provided from the two electrodes may be recombined in the light emitting layer to generate excitons, the generated excitons may be changed from an excited state to a ground state, and light may be emitted.

The self-light emitting display device that does not include a separate light source, such as a backlight unit, has low power consumption and may be configured in a lightweight and thin shape, and has also attracted attention as a next-generation display device because of its high-quality characteristics such as a wide viewing angle, high luminance and contrast, and a fast response speed.

As high-resolution display devices gradually emerge, the size of individual pixels is becoming smaller. Accordingly, the size of the components that constitute each pixel is gradually becoming smaller.

### SUMMARY

Embodiments of the disclosure provide a high-resolution display device by increasing pixel density.

However, embodiments of the disclosure are not restricted to those set forth herein. The above and other features of embodiments of the disclosure will become more apparent to one of ordinary skill in the art to which the disclosure pertains by referencing the detailed description of the disclosure given below.

According to an embodiment of the disclosure, a display device includes a light emitting element including a first electrode, a light emitting layer, and a second electrode, a first transistor including a first source electrode, a first active area, a first drain electrode, and a first gate electrode, a second transistor including a second source electrode, a second active area, a second drain electrode, and a second gate electrode, and a third transistor including a third source electrode, a third active area, a third drain electrode, and a third gate electrode, where the first source electrode is connected to the first electrode, the second source electrode is connected to the first gate electrode, the third drain electrode is connected to the first source electrode, the second gate electrode and the third gate electrode are defined by a same conductive line, and the second active area and the third active area are disposed in different layers.

In an embodiment, the display device may further include a gate line connected to the second gate electrode and the third gate electrode, where the gate line applies a first gate voltage to the second gate electrode and a second gate voltage to the third gate electrode.

In an embodiment, the same conductive line defining the second gate electrode and the third gate electrode may be a portion of the gate line.

In an embodiment, the first gate voltage and the second gate voltage may be applied to the gate line at different timings.

In an embodiment, the display may further include, a first conductive layer in which the second gate electrode and the third gate electrode are disposed, a first active layer disposed below the first conductive layer, and a second active layer disposed above the first conductive layer, where one of the second active area and the third active area is defined by a portion of the first active layer, and the other of the second active area and the third active area is defined by a portion of the second active layer.

In an embodiment, one of the second transistor and the third transistor may have a bottom gate structure, and the other of the second transistor and the third transistor may have a top gate structure.

In an embodiment, the second transistor and the third transistor may be disposed to be spaced apart from each other in a plan view.

In an embodiment, the second transistor and the third transistor may be disposed to overlap each other in the plan view.

In an embodiment, the second active area and the third active area may be disposed to overlap each other in the plan view.

In an embodiment, the second gate electrode and the third gate electrode may be disposed to overlap each other in the plan view.

In an embodiment, an extension direction of the second active area and an extension direction of the third active area are different from each other in the plan view.

According to an embodiment of the disclosure, a display device includes a substrate, a first active layer disposed on the substrate, a first conductive layer disposed on the first active layer, a second active layer disposed on the first conductive layer, a second conductive layer disposed on the first conductive layer, a light emitting element disposed on the second conductive layer, a first transistor including a first source electrode, a first active area, a first drain electrode, and a first gate electrode, a second transistor including a second source electrode, a second active area, a second drain electrode, and a second gate electrode, and a third transistor including a third source electrode, a third active area, a third drain electrode, and a third gate electrode, where the first gate electrode, the second gate electrode, and the third gate electrode are defined by portions of the first conductive layer, and one of the second active area and the third active area is defined by a portion of the first active layer, and the other of the second active area and the third active area is defined by a portion of the second active layer.

In an embodiment, the second transistor and the third transistor may be disposed to be spaced apart from each other.

In an embodiment, the second transistor and the third transistor may be disposed to overlap each other.

In an embodiment, the display device may further include a third conductive layer disposed between the second conductive layer and the light emitting element, where one of the second drain electrode and the third drain electrode is defined by a portion of the third conductive layer, and one of the second source electrode and the third source electrode is defined by a portion of the third conductive layer.

In an embodiment, the display device may further include a first passivation film disposed on the second active layer, where the first passivation film covers one of the second active area and the third active area in a plan view.

In an embodiment, the display device may further include a first connection electrode connecting the light emitting element and the first source electrode, where the first connection electrode is defined by a portion of the second active layer.

In an embodiment, the display device may further include a first via film disposed on the first passivation film, where the first connection electrode does not overlap the first passivation film in the plan view, and the first via film covers the first connection electrode in the plan view.

According to an embodiment of the disclosure, an electronic device includes a display device, the display device including, a light emitting element including a first electrode, a light emitting layer, and a second electrode, a first transistor including a first source electrode, a first active area, a first drain electrode, and a first gate electrode, a second transistor including a second source electrode, a second active area, a second drain electrode, and a second gate electrode, and a third transistor including a third source electrode, a third active area, a third drain electrode, and a third gate electrode, wherein the first source electrode is connected to the first electrode, the second source electrode is connected to the first gate electrode, the third drain electrode is connected to the first source electrode, the second gate electrode and the third gate electrode are defined by a same conductive line, and the second active area and the third active area are disposed in different layers.

According to an embodiment of the disclosure, an electronic device includes a display device, the display device including, a substrate, a first active layer disposed on the substrate, a first conductive layer disposed on the first active layer, a second active layer disposed on the first conductive layer, a second conductive layer disposed on the first conductive layer, a light emitting element disposed on the second conductive layer, a first transistor including a first source electrode, a first active area, a first drain electrode, and a first gate electrode, a second transistor including a second source electrode, a second active area, a second drain electrode, and a second gate electrode, and a third transistor including a third source electrode, a third active area, a third drain electrode, and a third gate electrode, wherein the first gate electrode, the second gate electrode, and the third gate electrode are defined by portions of the first conductive layer, and one of the second active area and the third active area is defined by a portion of the first active layer, and the other of the second active area and the third active area is defined by a portion of the second active layer.

According to the display device according to an embodiment of the disclosure, the high-resolution display device may be implemented by increasing pixel density.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other features of embodiments of the disclosure will become more apparent by describing in detail embodiments thereof with reference to the attached drawings, in which:

FIG. 1 is a schematic perspective view illustrating a display device according to an embodiment;

FIG. 2 is a schematic cross-sectional view of the display device taken along line X1-X1′ of FIG. 1;

FIG. 3 is a schematic plan view illustrating a display device according to an embodiment;

FIG. 4 is a schematic plan view illustrating a pad area of the display device according to an embodiment;

FIG. 5 is a plan view schematically illustrating a portion of a display area of a display substrate according to an embodiment;

FIG. 6 is a plan view schematically illustrating a portion of a display area of a display substrate according to another embodiment;

FIG. 7 is a cross-sectional view taken along line X2-X2′ of FIG. 5;

FIG. 8 is an equivalent circuit diagram of a pixel according to an embodiment;

FIG. 9 is a plan view illustrating a circuit layer according to an embodiment;

FIG. 10 is a cross-sectional view taken along lines X3-X3′ and X4-X4′ of FIG. 9;

FIG. 11 is a plan view illustrating a circuit layer according to another embodiment;

FIG. 12 is a cross-sectional view taken along lines X5-X5′ and X6-X6′ of FIG. 11;

FIG. 13 is a plan view illustrating a circuit layer according to still another embodiment;

FIG. 14 is a cross-sectional view taken along lines X7-X7′ and X8-X8′ of FIG. 13;

FIG. 15 is a plan view illustrating a circuit layer according to still another embodiment;

FIG. 16 is a cross-sectional view taken along lines X9-X9′ and X10-X10′ of FIG. 15;

FIG. 17 is a cross-sectional view illustrating a display substrate according to still another embodiment;

FIG. 18 is a plan view illustrating a circuit layer according to still another embodiment; and

FIG. 19 is a cross-sectional view taken along lines X11-X11′ and X12-X12′ of FIG. 18.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. Like reference numerals refer to like elements throughout.

It will also be understood that when a layer is referred to as being “on” another layer or substrate, it can be directly on the other layer or substrate, or intervening layers may also be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

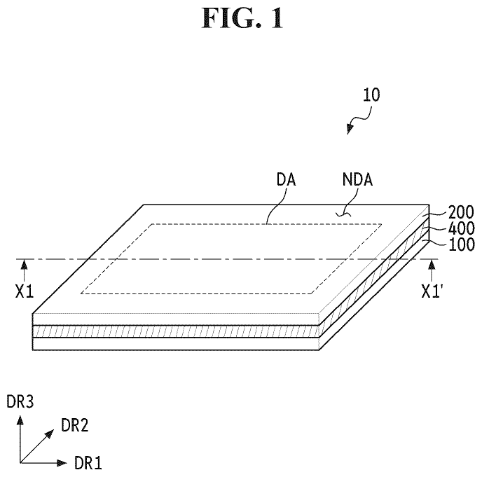

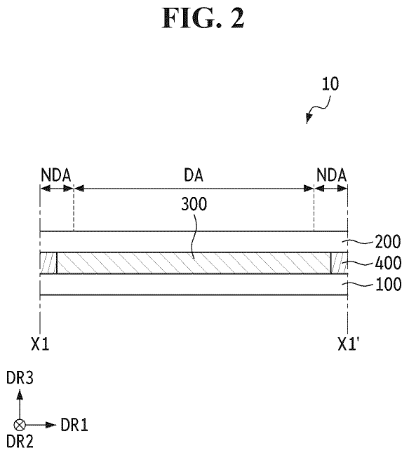

FIG. 1 is a schematic perspective view illustrating a display device according to an embodiment. FIG. 2 is a schematic cross-sectional view of the display device taken along line X1-X1′ of FIG. 1.

Referring to FIGS. 1 and 2, an embodiment of a display device 10 may be applied to various electronic devices such as small and medium-sized electronic equipment such as tablet computers, smartphones, car navigation units, cameras, displays provided in automobiles, wristwatch-type electronic devices, personal digital assistants (PDAs), portable multimedia players (PMPs), and game machines, medium and large-sized electronic equipment such as televisions, external billboards, monitors, personal computers, notebook computers, and the like. These electronic devices are presented only as examples, and the display device 10 may also be employed in other electronic devices without departing from the concept of the disclosure.

In an embodiment, the display device 10 may have a rectangular shape in a plan view. The display device 10 may include two long sides extending in a first direction DR1 and two short sides extending in a second direction DR2 intersecting the first direction DR1. A corner where the long side and the short side of the display device 10 meet may be a right angle, but is not limited thereto, and may form a curved surface. In another embodiment, the long side may extend in the second direction DR2, and the short side may extend in the first direction DR1. The planar shape of the display device 10 is not limited to the illustrated shape, and a circular shape or other shapes may also be applied.

In the illustrated drawings, the first direction DR1 and the second direction DR2 are horizontal directions and intersect each other. For example, the first direction DR1 and the second direction DR2 may be orthogonal to each other. In addition, a third direction DR3 may be a vertical direction intersecting the first direction DR1 and the second direction DR2, for example, a direction orthogonal to the first direction DR1 and the second direction DR2. Here, the third direction DR3 may be a thickness direction of the display device 10. Unless otherwise defined, in the specification, directions indicated by arrows in the first to third directions DR1, DR2, and DR3 may be referred to as one side, and the opposite directions thereof may be referred to as the other side. In addition, in the specification, “on”, “upper side”, “upper portion”, “top”, and “upper surface” refer to a direction in which an arrow in the drawing is directed in a third direction DR3 based on the drawing, and “below”, “lower side”, “lower portion”, “bottom”, and “lower surface” refer to a direction opposite to the direction in which the arrow in the third direction DR3 is directed based on the drawing. In addition, in the specification, “in a plan view” means when viewed in the third direction DR3.

The display device 10 may include a display area DA in which an image is displayed and a non-display area NDA in which an image is not displayed. In an embodiment, the non-display area NDA may be positioned around the display area DA and surround the display area DA.

A schematic stacked structure of the display device 10 will hereinafter be described. In an embodiment, the display device 10 includes a display substrate 100 and a color conversion substrate 200 disposed opposite to the display substrate 100, and may further include a sealing portion 400 coupling the display substrate 100 and the color conversion substrate 200 to each other, and a filler 300 filled between the display substrate 100 and the color conversion substrate 200.

The display substrate 100 may include an element and circuits for displaying an image, for example, a pixel circuit such as a switching element, a pixel defining film defining a light emitting area and a non-light emitting area to be described later in the display area DA, and a self-light emitting element. In an embodiment, the self-light emitting element may include at least one of an organic light emitting diode, a quantum dot light emitting diode, an inorganic material-based micro light emitting diode (e.g., a micro LED), and an inorganic material-based nano light emitting diode (e.g., a nano LED). Hereinafter, for convenience of description, embodiments where the self-light emitting element is an organic light emitting diode will be mainly described by way of example.

The color conversion substrate 200 may be positioned on the display substrate 100 and may face the display substrate 100. In an embodiment, the color conversion substrate 200 may include a color conversion pattern for converting a color of incident light. In an embodiment, the color conversion pattern may include at least one selected from a color filter and a wavelength conversion pattern.

A sealing portion 400 may be positioned between the display substrate 100 and the color conversion substrate 200 in the non-display area NDA. The sealing portion 400 may be disposed along edges of the display substrate 100 and the color conversion substrate 200 in the non-display area NDA to surround the display area DA in a plan view (or when viewed in the third direction DR3). The display substrate 100 and the color conversion substrate 200 may be coupled to each other through the sealing portion 400.

In an embodiment, the sealing portion 400 may include or be made of an organic material. In an embodiment, for example, the scaling portion 400 may include or be made of an epoxy resin, but is not limited thereto.

A filler 300 may be positioned in a space between the display substrate 100 and the color conversion substrate 200 surrounded by the sealing portion 400. The filler 300 may fill between the display substrate 100 and the color conversion substrate 200.

In an embodiment, the filler 300 may include or be made of a material that may transmit light. In an embodiment, the filler 300 may include or be made of an organic material. In an embodiment, for example, the filler 300 may include or be made of a silicon organic material, an epoxy organic material, or the like, but is not limited thereto. According to another embodiment, the filler 300 may be omitted.

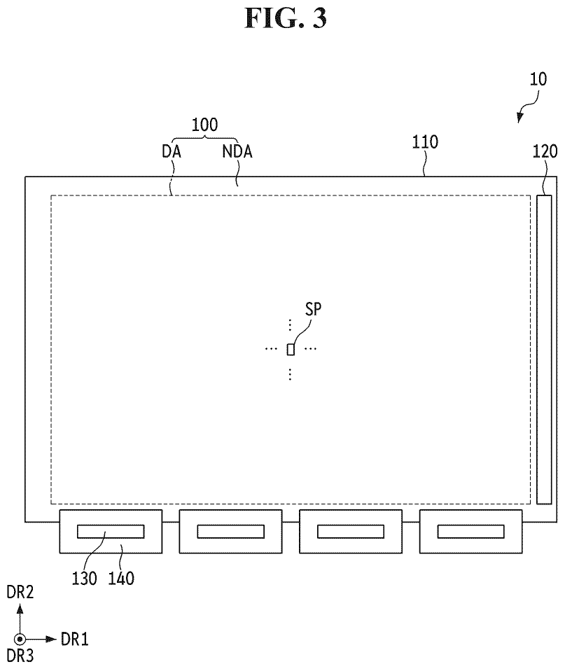

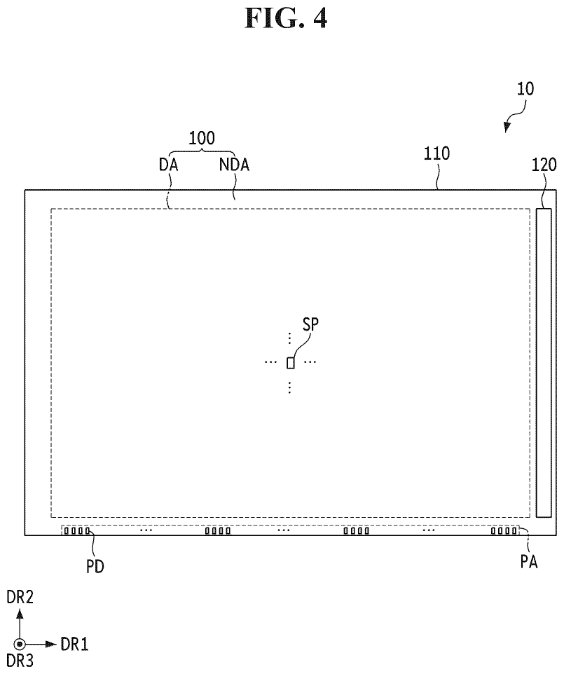

FIG. 3 is a schematic plan view illustrating a display device according to an embodiment. FIG. 4 is a schematic plan view illustrating a pad area of the display device according to an embodiment.

Referring to FIGS. 3 and 4, an embodiment of the display device 10 may include a display substrate 100 including pixels SP, and a first driver 120 and a second driver 130 that supply driving signals to the pixels SP. In some embodiments, the display device 10 may further include a power supply unit for supplying power voltages to the pixels SP, the first driver 120 and the second driver 130, and a timing control unit for controlling operations of the first driver 120 and the second driver 130.

The display substrate 100 may include a display area DA and a non-display area NDA. The display area DA may be an area that displays an image. The display area DA may include the pixels SP. In an embodiment, for example, the display area DA may include pixel areas in which each pixel SP is disposed. The non-display area NDA is the remaining area excluding the display area DA, and an image may not be displayed in the non-display area NDA. In an embodiment, the non-display area NDA may be positioned around the display area DA and surround the display area DA in a plan view.

The display substrate 100 may be provided as a rigid panel not to be substantially deformed, or may be provided as a flexible panel that may be deformed into a shape such as being folded, bent, or rolled in at least one portion. The display substrate 100 may be provided to the display device 10 in an unbent state or may be provided in a bent state in some sections.

The display substrate 100 may include a first substrate 110 and a pixel SP disposed on the first substrate 110. The pixel SP may be disposed in the display area DA on the first substrate 110.

The first substrate 110 is a base member for manufacturing or providing the display substrate 100 and may form a base surface of the display substrate 100. The first substrate 110 may include a display area DA and a non-display area NDA around the display area DA.

The display area DA may have various shapes depending on embodiments. In an embodiment, for example, the display area DA may have a quadrangular shape, a non-quadrangular polygonal shape, a circular shape, an oval shape, an irregular shape, or other shapes. In an embodiment, the display area DA may have a shape that matches the shape of the display substrate 100.

The pixels SP may be provided and/or arranged in the display area DA. In an embodiment, for example, the display area DA may include a plurality of pixel areas in which each pixel SP is disposed.

In an embodiment, the display device 10 may be a light emitting display device, and each pixel SP may include a light emitting element positioned in each light emitting area and a pixel circuit connected to the light emitting element. In describing the embodiments, “connection” may include electrical connection and/or physical connection. Each pixel circuit may include transistors (e.g., transistors, including a driving transistor that generates a driving current corresponding to a data signal, and at least one switching transistor), and at least one capacitor (e.g., a capacitor including a storage capacitor).

The non-display area NDA may include a pad area PA in which pads PD are disposed. In an embodiment, the non-display area NDA may further include a driving circuit area positioned on at least one side of the display area DA. At least one driver, pads PD, and/or lines may be disposed in the non-display area NDA.

At least one driver for driving the pixel SP, or a portion of the driver may be disposed in the driving circuit area. In an embodiment, for example, circuit elements constituting the first driver 120 (e.g., driver transistors and driver capacitors constituting stage circuits of the first driver 120) may be disposed in the driving circuit area on the first substrate 110. In an embodiment, the circuit elements of the first driver 120 may be formed within the display substrate 100 together with the pixels SP. In an embodiment, the driver transistors provided in the first driver 120 may be transistors of substantially the same or similar type and/or structure as the transistors provided in the pixels SP, and may be formed simultaneously with the transistors of the pixels SP.

The pads PD may be disposed in the pad area PA. At least one circuit board 140 may be disposed and/or bonded onto the pad area PA. In an embodiment, a plurality of circuit boards 140 connected to different pads PD may be disposed on the pad area PA. The pads PD may include signal pads and power pads for transmitting driving signals and power voltages necessary for driving the pixels SP and/or the first driver 120 to the inside of the display substrate 100.

The first driver 120 and the second driver 130 may generate driving signals for controlling an operation timing and luminance of the pixels SP, and supply the driving signals to the pixels SP. In an embodiment, for example, the first driver 120 may be a gate driver including a scan driver, and may be connected to the pixels SP through the respective gate lines. The first driver 120 may supply the respective gate signals (e.g., control signals that control driving timing of the pixels SP, including scan signals and/or emission control signal) to the pixels SP. The second driver 130 may be a data driver including source driving circuits and may be connected to the pixels SP through the respective data lines. The second driver 130 may supply the respective data signals to the pixels SP.

In an embodiment, at least one of the first driver 120 and the second driver 130, or a portion of the at least one driver may be embedded in the display substrate 100. In an embodiment, for example, the first driver 120 or a portion of the first driver 120 may be disposed on the first substrate 110 of the display substrate 100 and may be disposed and/or formed in the non-display area NDA.

FIG. 3 illustrates an embodiment where the first driver 120 is formed on one side of the display area DA (e.g., the non-display area NDA on the right side of the display area DA), but the embodiments are not limited thereto. In another embodiment, for example, the first driver 120 may be positioned only on the other side of the display area DA (e.g., the non-display area NDA on the left side of the display area DA), or may be positioned on both sides of the display area DA (e.g., non-display areas NDA on the left and right sides of the display area DA). Alternatively, a portion of the first driver 120 may be positioned in the non-display area NDA, and another portion of the first driver 120 may be positioned in the non-light emitting area (e.g., an area between the light emitting areas of the pixels SP) inside the display area DA.

In an embodiment, the other of the first driver 120 and the second driver 130, or a portion thereof, may be disposed or formed outside the display substrate 100 and may be electrically connected to the display substrate 100. In an embodiment, for example, the second driver 130 may be implemented with a plurality of integrated circuit chips and may be disposed on the circuit board 140 electrically connected to the pixel SP of the display substrate 100. The second driver 130 may be implemented with at least one integrated circuit chip and may be mounted on the non-display area NDA of the display substrate 100.

The circuit board 140 may be connected to the display substrate 100 through the pads PD. In an embodiment, the circuit board 140 may be a flexible film such as a flexible printed circuit board (FPCB), a printed circuit board (PCB), or a chip on film (COF), but is not limited thereto. In an embodiment, the circuit board 140 may be connected to the timing control unit and/or the power supply unit through another circuit board or a connector.

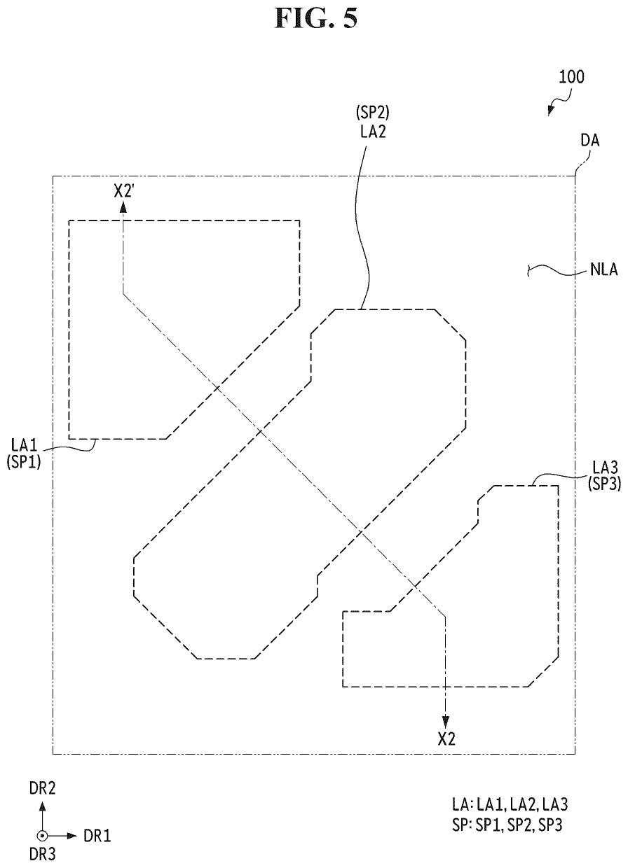

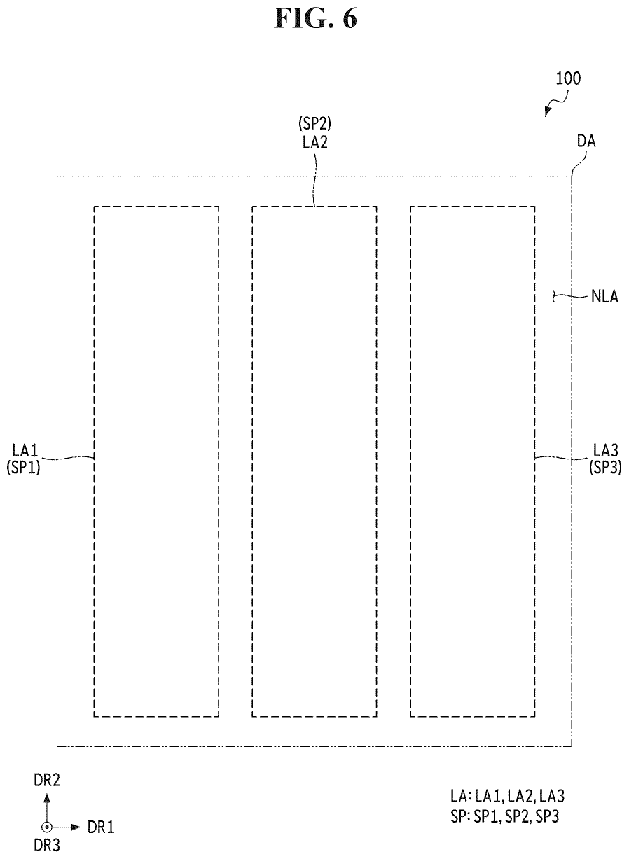

FIG. 5 is a plan view schematically illustrating a portion of a display area of a display substrate according to an embodiment. FIG. 6 is a plan view schematically illustrating a portion of a display area of a display substrate according to another embodiment.

Referring to FIGS. 5 and 6 in addition to FIGS. 1 and 2, in an embodiment, a plurality of light emitting areas LA and a non-light emitting area NLA may be defined in the display area DA of the display substrate 100. The plurality of light emitting areas LA may be areas in which light generated by the light emitting element of the display substrate 100 is emitted to the outside of the display substrate 100, and the non-light emitting area NLA may be an area in which the light generated by the light emitting element of the display substrate 100 is not emitted to the outside of the display substrate 100. In some embodiments, the plurality of light emitting areas LA may include a first light emitting area LA1, a second light emitting area LA2, and a third light emitting area LA3.

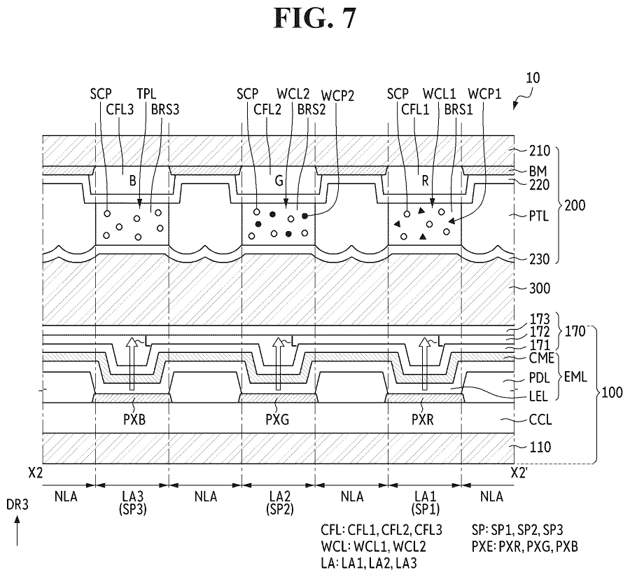

In some embodiments, the light emitting area LA and the non-light emitting area NLA may be defined by a pixel defining film PDL (see FIG. 7). In an embodiment, for example, the light emitting area LA may be an area that overlaps an opening of the pixel defining film PDL (see FIG. 7), and the non-light emitting area NLA may be an area that does not overlap the opening of the pixel defining film PDL (sec FIG. 7).

In an embodiment, light emitted by the display substrate 100 to the color conversion substrate 200 in the plurality of light emitting areas LA may be light of a third color. In an embodiment, for example, the light of the third color may be blue light, and may have a peak wavelength in a range of about 440 nanometers (nm) to about 480 nm. The peak wavelength may refer to a wavelength at which intensity is maximized within a wavelength region. However, the light emitted by the display substrate 100 to the color conversion substrate 200 in the plurality of light emitting areas LA is not limited thereto, and may also be light in an ultraviolet region.

In an embodiment where the first to third light emitting areas LA1, LA2, and LA3 emit light of a same color, the first to third pixels SP1, SP2, and SP3 may express various colors based on color conversion patterns included in the color conversion substrate 200.

In another embodiment, the first to third light emitting areas LA1, LA2, and LA3 may also emit light of different colors. In an embodiment, for example, the light emitted from the first light emitting area LA1 may be red light, the light emitted from the second light emitting area LA2 may be green light, and the light emitted from the third light emitting area LA3 may be blue light.

The first light emitting area LA1, the second light emitting area LA2, and the third light emitting area LA3 may constitute the first pixel SP1, the second pixel SP2, and the third pixel SP3, respectively. The first light emitting area LA1, the second light emitting area LA2, and the third light emitting area LA3 may be repeatedly disposed along the first direction DR1 and the second direction DR2 throughout the display area DA. The first light emitting area LA1, the second light emitting area LA2, and the third light emitting area LA3 may form one unit color pixel.

In an embodiment, as illustrated in FIG. 5, the first to third light emitting areas LA1, LA2, and LA3 may be disposed in a diagonal direction with respect to the first direction DR1 and the second direction DR2. In an embodiment, for example, in one unit color pixel, the first light emitting area LA1 may be generally disposed at an upper left end in a plan view, the second light emitting area LA2 may generally be disposed at the center in the plan view, and the third light emitting area LA3 may be generally disposed at a lower right end in the plan view. However, the arrangement order of the first to third light emitting areas LA1, LA2, and LA3 is not limited thereto.

In another embodiment, as illustrated in FIG. 6, the first to third light emitting areas LA1, LA2, and LA3 may be disposed along the first direction DR1. In an embodiment, for example, in one unit color pixel, the first light emitting area LA1 may be generally disposed on a left side in a plan view, the second light emitting area LA2 may generally be disposed at the center in a plan view, and the third light emitting area LA3 may be generally disposed on a right side in a plan view. However, the arrangement order of the first to third light emitting areas LA1, LA2, and LA3 is not limited thereto.

In an embodiment, as illustrated in FIG. 5, the first light emitting area LA1 may have a polygonal shape extending in the first direction DRI and the second direction DR2. In the drawings, the shape of the first light emitting area LA1 is illustrated as a pentagon as an example. The second light emitting area LA2 may have a polygonal shape extending in a diagonal direction with respect to the first direction DRI and the second direction DR2. In the drawings, the shape of the second light emitting area LA2 is illustrated as a polygon including steps at both ends as an example. The third light emitting area LA3 may have a polygonal shape extending in the first direction DR1 and the second direction DR2. In the drawings, the shape of the third light emitting area LA3 is illustrated as a polygon including a portion protruding in a direction opposite to the first direction DR1 and in the second direction DR2 as an example. However, the shapes of the first to third light emitting areas LA1, LA2, and LA3 are not limited thereto.

In another embodiment, as illustrated in FIG. 6, the first to third light emitting areas LA1, LA2, and LA3 may have a polygonal shape extending in the second direction DR2. In the drawings, the shape of the first to third light emitting areas LA1, LA2, and LA3 is illustrated as a quadrangle as an example, However, the shapes of the first to third light emitting areas LA1, LA2, and LA3 are not limited thereto.

In an embodiment, as illustrated in FIG. 5, the widths and shapes of the first to third light emitting areas LA1, LA2, and LA3 may be different from each other. In an embodiment, for example, the first light emitting area LA1 may have a similar width in the first direction DR1 and the second direction DR2. The second light emitting area LA2 may have a wide width in the diagonal direction with respect to the first direction DR1 and the second direction DR2, and may have a narrow width in the diagonal direction with respect to the first direction DR1 and the second direction DR2. Therefore, the second light emitting area LA2 may have a polygonal shape that is generally long in the diagonal direction with respect to the first direction DR1 and the second direction DR2. The third light emitting area LA3 may have a similar width in the first direction DR1 and the second direction DR2.

In another embodiment, as illustrated in FIG. 6, the widths and shapes of the first to third light emitting areas LA1, LA2, and LA3 may be the same as each other. In an embodiment, for example, the widths of the first to third light emitting areas LA1, LA2, and LA3 in the first direction DR1 may be the same as each other, and the widths of the first to third light emitting areas LA1, LA2, and LA3 in the second direction DR2 may be the same as each other.

The non-light emitting area NLA may be positioned around the light emitting area LA of the display substrate 100 within the display area DA. The non-light emitting area NLA may be positioned not only around the light emitting area LA but also between the first light emitting area LA1 and the second light emitting area LA2, between the second light emitting area LA2 and the third light emitting area LA3, and between the third light emitting area LA3 and the first light emitting area LA1.

Light emitted from the light emitting area LA of the display substrate 100 may transmit through a light transmitting area of the color conversion substrate 200 and be provided to the outside of the display device 10.

FIG. 7 is a cross-sectional view taken along line X2-X2′ of FIG. 5.

Referring to FIG. 7 in addition to FIGS. 5 and 6, an embodiment of the display device 10 may include a display substrate 100, a color conversion substrate 200 facing the display substrate 100, and a filler 300 that adheres the display substrate 100 and the color conversion substrate 200 to each other.

The display substrate 100 may include a first substrate 110, a circuit layer CCL, a light emitting element layer EML, and an encapsulation structure 170.

The first substrate 110 may include a transparent material. In an embodiment, for example, the first substrate 110 may include a transparent insulating material such as glass or quartz. The first substrate 110 may be a rigid substrate. However, the first substrate 110 is not limited thereto, and the first substrate 110 may include plastic such as polyimide, and may have flexible characteristics that may be curved, bent, folded, or rolled.

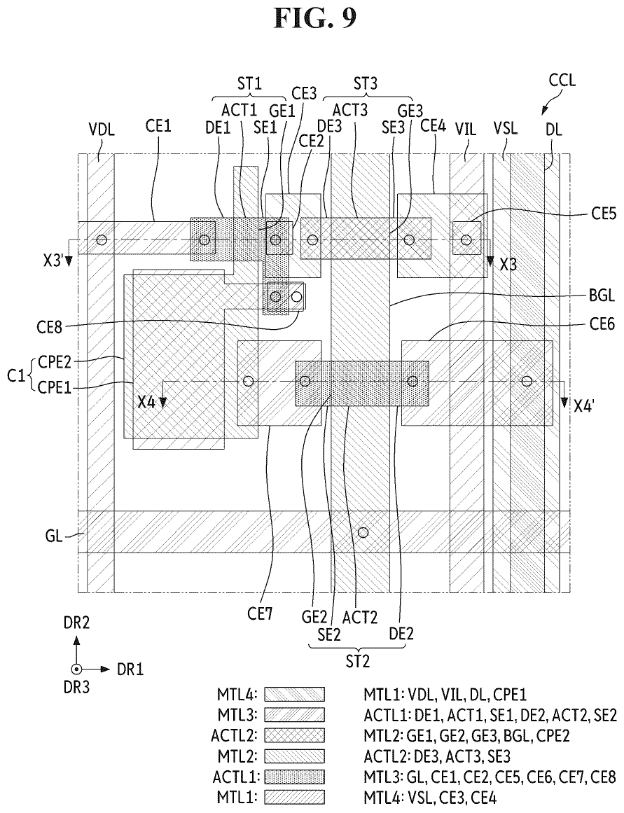

The circuit layer CCL (e.g., a thin film transistor layer) may be disposed on the first substrate 110. The circuit layer CCL will be described later with reference to FIG. 9 and the like.

The light emitting element layer EML may be disposed on the circuit layer CCL. The light emitting element layer EML may include a pixel electrode PXE, a pixel defining film PDL, a light emitting layer LEL, and a common electrode CME.

The pixel electrode PXE may be a first electrode of a light emitting diode, for example, an anode electrode. The pixel electrode PXE may have a stacked film structure in which a material layer having a high work function, such as indium tin oxide (ITO), indium zinc oxide (IZO), zinc oxide (ZnO), or indium oxide (In₂O₃) and a reflective material layer such as silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or mixtures thereof are stacked. The material layer having the high work function may be disposed on a layer above the reflective material layer and be disposed close to the light emitting layer LEL. The pixel electrodes PXE may have a multi-layer structure of ITO/Mg, ITO/MgF, ITO/Ag, and ITO/Ag/ITO, but is not limited thereto.

The pixel electrode PXE may include a first pixel electrode PXR, a second pixel

electrode PXG, and a third pixel electrode PXB. The first pixel electrode PXR may be disposed to overlap the first light emitting area LA1 in the third direction DR3. The second pixel electrode PXG may be disposed to overlap the second light emitting area LA2 in the third direction DR3. The third pixel electrode PXB may be disposed to overlap the third light emitting area LA3 in the third direction DR3.

The pixel defining film PDL may be disposed on one surface of the first substrate 110 along a boundary of the pixel SP. The pixel defining film PDL may be disposed on the pixel electrode PXE and may define or be provided with an opening exposing the pixel electrode PXE. The light emitting area LA and the non-light emitting area NLA may be divided by the pixel defining film PDL and the opening thereof.

The pixel defining film PDL may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB). The pixel defining film PDL may also include an inorganic material.

The light emitting layer LEL may be disposed on the pixel electrode PXE exposed by the pixel defining film PDL. The light emitting layer LEL may be not only in contact with the pixel electrode PXE but also in contact with side and upper surfaces of the pixel defining film PDL. The light emitting layer LEL may be connected without distinction between the light emitting areas LA and the pixels SP. The light emitting layer LEL may be entirely or commonly provided the light emitting areas LA and the pixels SP without distinction between the light emitting areas LA and the pixels SP. Accordingly, a wavelength of light emitted by the light emitting layer LEL may be the same for each of the light emitting areas LA1, LA2, and LA3. In such an embodiment, as the light emitting layer LEL of each of the light emitting areas LA1, LA2, and LA3 emits blue light or ultraviolet light and the color conversion substrate 200, which will be described later, includes a wavelength conversion layer WCL, a color for each pixel SP may be displayed.

In another embodiment, the light emitting layer LEL may be disposed to be spaced apart from each other in each of the light emitting areas LA1, LA2, and LA3 divided by the pixel defining film PDL. In such an embodiment, a wavelength of light emitted by each light emitting layer LEL may be the same for each of the light emitting areas LA1, LA2, and LA3.

In an embodiment in which the display device 10 is an organic light emitting display device, the light emitting layer LEL may include an organic layer including an organic material. The organic layer may include an organic light emitting layer, and may further include at least one of a hole injection layer, a hole transporting layer, an electron transporting layer, and an electron injection layer as an auxiliary layer assisting light emission in some cases. In another embodiment, when the display device 10 is a micro LED display device or a nano LED display device, the light emitting layer LEL may include an inorganic material such as an inorganic semiconductor.

In some embodiments, the light emitting layer LEL may have a tandem structure including a plurality of organic light emitting layers disposed to overlap each other in the thickness direction (or the third direction DR3) and a charge generating layer disposed between the organic light emitting layers. The respective organic light emitting layers disposed to overlap each other may emit light of a same wavelength, or emit light of different wavelengths. At least partial layer of the light emitting layer LEL of each pixel SP may be separated from or connected to a same layer of a neighboring pixel SP by the pixel defining film PDL.

The common electrode CME may be disposed on the light emitting layer LEL. The common electrode CME may be connected without distinction between the light emitting area LA and the pixel SP. The common electrode CME may be a front electrode that is entirely disposed without distinction between the light emitting area LA and the pixel SP. The common electrode CME may be a second electrode of a light emitting diode, for example, a cathode electrode. The common electrode CME may include a material layer having a small work function, such as Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.). The common electrode CME may further include a transparent metal oxide layer disposed on the material layer having the small work function.

The pixel electrode PXE, the light emitting layer LEL, and the common electrode CME may constitute a light emitting element (e.g., an organic light emitting element). The light emitted from the light emitting layer LEL may be emitted upward through the common electrode CME.

The encapsulation structure 170 may be disposed on the common electrode CME. The encapsulation structure 170 may include at least one thin film encapsulation layer. In an embodiment, for example, the encapsulation structure 170 may include a first encapsulation inorganic film 171, an encapsulation organic film 172, and a second encapsulation inorganic film 173.

The first encapsulation inorganic film 171 may be disposed on the light emitting element layer EML. The first encapsulation inorganic film 171 may include silicon nitride (SiNₓ), silicon oxide (SiOₓ), silicon oxynitride (SiOₓN_{y}), or the like.

The encapsulation organic film 172 may be disposed on the first encapsulation inorganic film 171. The encapsulation organic film 172 may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB).

The second encapsulation inorganic film 173 may be disposed on the encapsulation organic film 172. The second encapsulation inorganic film 173 may include the same material as the first encapsulation inorganic film 171 described above. In an embodiment, for example, the second encapsulation inorganic film 173 may include silicon nitride (SiNₓ), silicon oxide (SiOₓ), silicon oxynitride (SiOₓN_{y}), or the like.

In some embodiments, at least one of the layers of the encapsulation structure 170 or the entire encapsulation structure 170 may be omitted. In an embodiment where the encapsulation structure 170 is omitted, the filler 300, the sealing portion 400, and the color conversion substrate 200 may be directly disposed on the light emitting element layer EML, and the filler 300, the sealing portion 400, and the color conversion substrate 200 may directly perform an encapsulation function.

The color conversion substrate 200 may be disposed to face the display substrate 100 on the encapsulation structure 170. The color conversion substrate 200 may include a second substrate 210, a light blocking member BM, a color filter layer CFL, a first capping layer 220, a partition wall PTL, a wavelength conversion layer WCL, a light transmitting layer TPL, and a second capping layer 230.

The second substrate 210 may include a transparent material. The second substrate 210 may include a transparent insulating material such as glass or quartz. The second substrate 210 may be a rigid substrate. However, the second substrate 210 is not limited thereto, and may include plastic such as polyimide, and may have flexible characteristics that may be curved, bent, folded, or rolled.

In an embodiment, the second substrate 210 may be a same substrate as the first substrate 110, but not being limited thereto. In an embodiment, the material, thickness, transmittance, etc. of the second substrate 210 may be different from those of the first substrate 110. In an embodiment, for example, the second substrate 210 may have a higher transmittance than the first substrate 110. In an embodiment, for example, the second substrate 210 may be thicker or thinner than the first substrate 110.

The light blocking member BM may be disposed along the boundary of the pixel SP on one surface of the second substrate 210 facing the first substrate 110. The light blocking member BM may overlap the pixel defining film PDL of the display substrate 100 and may be positioned in the non-light emitting area NLA. The light blocking member BM may include an opening exposing one surface of the second substrate 210 that overlaps the light emitting area LA. The light blocking member BM may be formed in a lattice shape in a plan view.

The light blocking member BM may include an organic material. The light blocking member BM may reduce distortion in color due to reflection of external light by absorbing the external light. In addition, the light blocking member BM may serve to prevent the light emitted from the light emitting layer LEL from permeating into the adjacent pixel SP.

In an embodiment, the light blocking member BM may absorb all visible light wavelengths. The light blocking member BM may include a light absorbing material. In an embodiment, for example, the light blocking member BM may include or be made of a material used as a black matrix of the display device 10.

In another embodiment, the light blocking member BM may absorb light of a specific wavelength of the visible light wavelengths and transmit light of another specific wavelength. In an embodiment, the light blocking member BM may include a same material as the color filter layer CFL. In an embodiment, for example, the light blocking member BM may include or be made of a same material as a blue color filter layer. In some embodiments, the light blocking member BM may also be formed integrally with the blue color filter layer as a single unitary indivisible part. In another embodiment, the light blocking member BM may also be omitted.

The color filter layer CFL may be disposed on one surface of the second substrate 210 where the light blocking member BM is disposed. The color filter layer CFL may be disposed on one surface of the second substrate 210 exposed through the opening of the light blocking member BM. Furthermore, the color filter layer CFL may be partially disposed on an adjacent light blocking member BM.

The color filter layer CFL may include a first color filter layer CFL1 disposed in the first pixel SP1, a second color filter layer CFL2 disposed in the second pixel SP2, and a third color filter layer CFL3 disposed in the third pixel SP3. Each color filter layer CFL may include a colorant such as a dye or pigment that absorbs wavelengths other than the corresponding color wavelength. The first color filter layer CFL1 may be a red color filter layer, the second color filter layer CFL2 may be a green color filter layer, and the third color filter layer CFL3 may be a blue color filter layer. It is illustrated in the drawings that the color filter layers CFL adjacent to each other are disposed to be spaced apart from each other on the light blocking member BM, but the color filter layers CFL adjacent to each other may at least partially overlap each other on the light blocking member BM.

The first capping layer 220 may be disposed on the color filter layer CFL. The first capping layer 220 may prevent impurities such as moisture or air from permeating from the outside to damage or contaminate the color filter layer CFL. In addition, the first capping layer 220 may prevent the colorant of the color filter layer CFL from diffusing to other components.

The first capping layer 220 may be in direct contact with one surface (lower surface in FIG. 7) of the color filter layer CFL. The first capping layer 220 may include or be made of an inorganic material. In an embodiment, for example, the first capping layer 220 may include at least one selected from silicon nitride, aluminum nitride, zirconium nitride, titanium nitride, hafnium nitride, tantalum nitride, silicon oxide, aluminum oxide, titanium oxide, tin oxide, and silicon oxynitride.

The partition wall PTL may be disposed on the first capping layer 220. The partition wall PTL may be positioned in the non-light emitting area NLA. The partition wall PTL may be disposed to overlap the light blocking member BM. The partition wall PTL may be provided with an opening exposing the color filter layer CFL. The partition wall PTL may include a photosensitive organic material, but is not limited thereto. The partition wall PTL may further include a light blocking material.

The wavelength conversion layer WCL and/or the light transmitting layer TPL may be disposed in a space exposed by the opening of the partition wall PTL. The wavelength conversion layer WCL and the light transmitting layer TPL may be formed through an inkjet process using the partition wall PTL as a bank, but are not limited thereto.

In an embodiment in which the light emitting layer LEL of each pixel SP emits a third color, the wavelength conversion layer WCL may include a first wavelength conversion pattern WCL1 disposed in the first pixel SP1 and a second wavelength conversion pattern WCL2 disposed in the second pixel SP2. The light transmitting layer TPL may be disposed in the third pixel SP3.

The first wavelength conversion pattern WCL1 may include a first base resin BRS1 and a first wavelength conversion material WCP1 disposed in the first base resin BRS1. The second wavelength conversion pattern WCL2 may include a second base resin BRS2 and a second wavelength conversion material WCP2 disposed in the second base resin BRS2. The light transmitting layer TPL may include a third base resin BRS3 and scatterers SCP disposed in the third base resin BRS3.

The first to third base resins BRS1, BRS2, and BRS3 may include a light transmitting organic material. In an embodiment, for example, the first to third base resins BRS1, BRS2, and BRS3 may include an epoxy resin, an acrylic resin, a cardo resin, or an imide resin. All of the first to third base resins BRS1, BRS2, and BRS3 may include or be made of a same material as each other, but are not limited thereto.

The scatterers SCP may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), or the like, and examples of a material of the organic particle may include an acrylic resin, a urethane resin, or the like.

The first wavelength conversion material WCP1 may be a material that converts the third color into the first color, and the second wavelength conversion material WCP2 may be a material that converts the third color into the second color. The first wavelength conversion material WCP1 and the second wavelength conversion material WCP2 may be quantum dots, quantum rods, phosphors, or the like. The quantum dot may include group IV nanocrystals, group II-VI compound nanocrystals, group III-V compound nanocrystals, group IV-VI nanocrystals, or a combination thereof. The first wavelength conversion pattern WCL1 and the second wavelength conversion pattern WCL2 may further include a scatterer SCP that increases wavelength conversion efficiency.

The light transmitting layer TPL disposed in the third pixel SP3 may transmit light of the third color emitted from the light emitting layer LEL while maintaining a wavelength thereof. The scatterers SCP of the light transmitting layer TPL may serve to adjust an emission path of the light emitted through the light transmitting layer TPL. The light transmitting layer TPL may not include a wavelength conversion material.

The second capping layer 230 may be disposed on the wavelength conversion layer WCL, the light transmitting layer TPL, and the partition wall PTL. The second capping layer 230 may include or be made of an inorganic material. The second capping layer 230 may include at least one selected from the materials listed as materials for the first capping layer 220. The second capping layer 230 and the first capping layer 220 may include or be made of a same material as each other, but are not limited thereto.

The filler 300 may be disposed between the display substrate 100 and the color conversion substrate 200. The filler 300 may fill a space between the display substrate 100 and the color conversion substrate 200 and may serve to bond and couple the display substrate 100 and the color conversion substrate 200 to each other. The filler 300 may be disposed between the encapsulation structure 170 of the display substrate 100 and the second capping layer 230 of the color conversion substrate 200. The filler 300 may include or be made of a Si-based organic material, an epoxy organic material, or the like, but is not limited thereto.

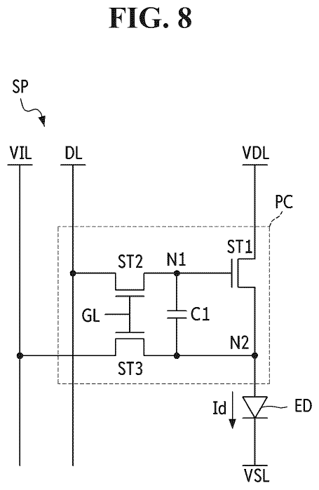

FIG. 8 is an equivalent circuit diagram of a pixel according to an embodiment.

Referring to FIG. 8 in addition to FIGS. 3 and 4, in an embodiment, each pixel SP may include a light emitting element ED and a pixel circuit PC connected to the light emitting clement ED. The light emitting element ED is a light source of the pixel SP and may be, for example, an organic light emitting diode, but is not limited thereto. The pixel circuit PC may control the light emitting timing and luminance of the light emitting element ED.

The pixel circuit PC may supply a driving current Id to the light emitting element ED in response to the driving signals supplied from the first driver 120 and the second driver 130. In an embodiment, for example, the pixel circuit PC may supply the driving current Id (or drain-source current) to the light emitting element ED in response to each gate signal supplied from the first driver 120 through each gate line GL, and a data signal supplied from the second driver 130 through the data line DL.

The pixel circuit PC may be connected to a first voltage line VDL, a data line DL, an initialization voltage line VIL, a gate line GL, and a second voltage line VSL. The first voltage line VDL may supply a first driving voltage (e.g., a high potential voltage or a pixel voltage) received from a power supply unit to the pixel circuit PC. The second voltage line VSL may supply a second driving voltage (e.g., a low potential voltage or a common voltage) received from the power supply unit to the pixel circuit PC. The data line DL may supply a data voltage received from the second driver 130 to pixel circuit PC. The gate line GL may supply a gate voltage received from the first driver 120 to pixel circuit PC. The initialization voltage line VIL may supply an initialization voltage received from the power supply unit to the pixel circuit PC, and may supply a sensing signal received from the pixel circuit PC to the power supply unit.

In some embodiments, the gate line GL may apply a first gate voltage supplied to a second transistor ST2 and a second gate voltage supplied to a third transistor ST3 through one line, e.g., a same single line. The first gate voltage may be a scan voltage, and the second gate voltage may be a sensing voltage. That is, in the display device 10 according to the embodiment, the first gate voltage supplied to the second transistor ST2 and the second gate voltage supplied to the third transistor ST3 may be each applied through the gate line GL, which is a common line. In some embodiments, the first gate voltage and the second gate voltage may be applied to the gate line GL from the first driver 120 at different timings. Accordingly, the first gate voltage and the second gate voltage may be prevented from interfering with each other. A structure of the gate line GL will be described later with reference to FIG. 9 and the like.

The pixel circuit PC may include transistors and at least one capacitor. In an embodiment, for example, the pixel circuit PC may include three transistors and one capacitor. That is, the pixel circuit PC may have a 3TIC (3 transistor 1 capacitor) structure. However, the pixel circuit PC is not limited thereto, and the number of transistors and capacitors in each pixel circuit may be modified in various ways. Hereinafter, for convenience of explanation, the 3TIC structure will be described as an example, but the disclosure is not limited thereto, and various other modified structures such as a 2TIC structure, a 7TIC structure, a 6TIC structure, and 17T3C structure may also be applied.

Although FIG. 8 illustrates an embodiment in which first to third transistors ST1, ST2, and ST3 are all N-type transistors, the types of transistors ST1, ST2, and ST3 are not limited thereto. In another embodiment, for example, at least one selected from the transistors ST1, ST2, and ST3 may be a P-type transistor.

The first transistor ST1 may be turned on by the data voltage applied through the data line DL and may electrically connect the first voltage line VDL and a first electrode of the light emitting element ED. The first transistor ST1 may be turned on based on the data voltage, thereby supplying the first driving voltage to the light emitting element ED. The first transistor ST1 may be a driving transistor that drives the light emitting element ED.

The first transistor ST1 may include a gate electrode, a drain electrode, and a source electrode. The gate electrode of the first transistor ST1 may be connected to a first node N1, the drain electrode of the first transistor ST1 may be connected to the first voltage line VDL, and the source electrode of the first transistor ST1 may be connected to a second node N2.

The second transistor ST2 may be turned on by a gate signal of the gate line GL and may electrically connect the data line DL and the first node N1, which is the gate electrode of the first transistor ST1, to each other. The second transistor ST2 may be turned on based on the first gate signal, thereby supplying the data voltage to the first node N1. The second transistor ST2 may be a switching transistor that controls a current flowing through the first transistor ST1 and the light emitting element ED.

The second transistor ST2 may include a gate electrode, a drain electrode, and a source electrode. The gate electrode of the second transistor ST2 may be connected to the gate line GL, the drain electrode of the second transistor ST2 may be connected to the data line DL, and the source electrode of the second transistor ST2 may be connected to the first node N1. The source electrode of the second transistor ST2 may be connected to the gate electrode of the first transistor ST1 and a second capacitor electrode of a first capacitor C1 through the first node N1.

The third transistor ST3 may be turned on by the gate signal of the gate line GL and may electrically connect the initialization voltage line VIL and the second node N2, which is the source electrode of the first transistor ST1, to each other. The third transistor ST3 may be turned on based on the second gate signal, thereby supplying the initialization voltage to the second node N2. The third transistor ST3 may be turned on based on the second gate signal, thereby supplying the sensing signal to the initialization voltage line VIL. The third transistor ST3 may be a switching transistor that controls a current flowing through the first transistor ST1 and the light emitting element ED. In addition, the third transistor ST3 may be a sensing transistor that controls the sensing signal of the pixel circuit PC.

The third transistor ST3 may include a gate electrode, a drain electrode, and a source electrode. The gate electrode of the third transistor ST3 may be connected to the gate line GL, the drain electrode of the third transistor ST3 may be connected to the second node N2, and the source electrode of the third transistor ST3 may be connected to the initialization voltage line VIL. The drain electrode of the third transistor ST3 may be connected to the source electrode of the first transistor ST1, a first capacitor electrode of the first capacitor C1, and the first electrode of the light emitting element ED through the second node N2.

The light emitting element ED may emit light by receiving the driving current Id. The amount (or intensity) of light emitted from or luminance of the light emitting element ED may be proportional to the magnitude of the driving current Id. The light emitting element ED may be an organic light emitting diode (LED) including an organic light emitting layer, a quantum dot LED including a quantum dot light emitting layer, a micro LED, or an inorganic LED including an inorganic semiconductor, but is not limited thereto.

The first electrode (e.g., the pixel electrode) of the light emitting element ED may be connected to the second node N2, and the second electrode of the light emitting element ED may be connected to the second voltage line VSL. The first electrode of the light emitting element ED may be connected to the source electrode of the first transistor ST1, the drain electrode of the third transistor ST3, and the first capacitor electrode of the first capacitor C1 through the second node N2.

The first capacitor CI may be connected between the first node N1 and the second node N2. The first capacitor C1, which is a storage capacitor of the pixel SP, may store a threshold voltage and a data signal of the first transistor ST1.

The first capacitor C1 may include a first capacitor electrode and a second capacitor electrode. The first capacitor electrode may be connected to the drain electrode of the third transistor ST3, and may be connected to the source electrode of the first transistor ST1 and the first electrode of the light emitting element ED through the second node N2. The second capacitor electrode may be connected to the source electrode of the second transistor ST2 and the gate electrode of the first transistor ST1 through the first node N1.

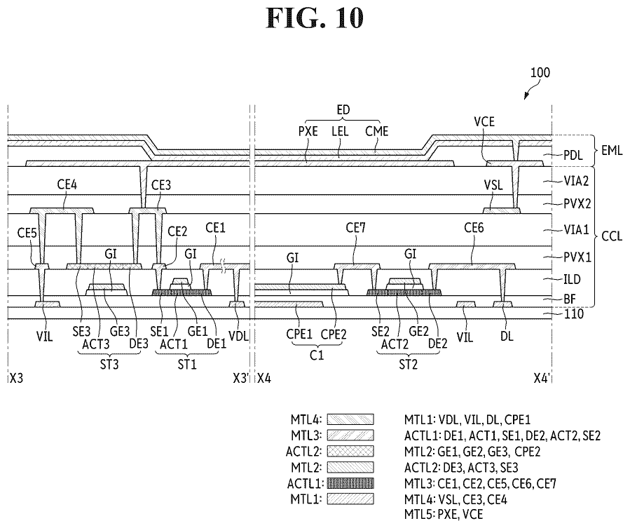

FIG. 9 is a plan view illustrating a circuit layer according to an embodiment. FIG. 10 is a cross-sectional view taken along lines X3-X3′ and X4-X4′ of FIG. 9.

Referring to FIGS. 9 and 10 in addition to FIGS. 5 to 8, FIG. 9 is a view illustrating a configuration of a circuit layer CCL, and FIG. 10 is a view illustrating a configuration of the first substrate 110 and the light emitting element layer EML in addition to the circuit layer CCL. FIGS. 9 and 10 illustrate a pixel circuit PC of one pixel SP and lines connected thereto, and the position and shape of each component may be changed in another pixel circuits PC of the first to third pixels SP1, SP2, and SP3.

The display substrate 100 may include a first substrate 110, a circuit layer CCL, and a light emitting clement layer EML. The first substrate 110 is substantially the same as that described above with reference to FIG. 7 and any repetitive detailed description thereof will thus be omitted.

The circuit layer CCL may be disposed on the first substrate 110. The circuit layer CCL (e.g., a thin film transistor layer) may include a first conductive layer MTL1, a buffer film BF, a first active layer ACTL1, a gate insulating film G1, a second conductive layer MTL2, an interlayer insulating film ILD, a second active layer ACTL2, a third conductive layer MTL3, a first passivation film PVX1, a first via film VIA1, a fourth conductive layer MTL4, a second passivation film PVX2, and a second via film VIA2.

The first conductive layer MTL1 may be disposed on the first substrate 110. The first conductive layer MTL1 may include a single layer or a multi-layer, each layer therein including at least one selected from molybdenum (Mo), aluminum (Al), chromium (Cr), gold (Au), titanium (Ti), nickel (Ni), neodymium (Nd), and copper (Cu), or an alloy thereof.

The first conductive layer MTL1 may include or define the first voltage line VDL, the initialization voltage line VIL, the data line DL, and the first capacitor electrode CPE1 of the first capacitor C1.

The buffer film BF may be disposed on the first conductive layer MTL1. The buffer film BF may include an inorganic material such as a silicon nitride layer, a silicon oxynitride layer, a silicon oxide layer, a titanium oxide layer, and an aluminum oxide layer. Alternatively, the buffer film BF may include a multi-film in which a plurality of layers of a silicon nitride layer, a silicon oxynitride layer, a silicon oxide layer, a titanium oxide layer, and an aluminum oxide layer are alternately stacked.

The first active layer ACTL1 may be disposed on the buffer film BF. The first active layer ACTL1 may include polycrystalline silicon, single crystal silicon, low-temperature polycrystalline silicon, amorphous silicon, or an oxide semiconductor material.

The first active layer ACTL1 may include or define a first active area ACT1, a first drain electrode DE1, and a first source electrode SE1 of the first transistor ST1, and a second active area ACT2, a second drain electrode DE2, and a second source electrode SE2 of the second transistor ST2.

The gate insulating film GI may be disposed on the active layer ACTL and the buffer film BF. The gate insulating film GI may include an inorganic film, for example, a silicon nitride layer, a silicon oxynitride layer, a silicon oxide layer, a titanium oxide layer, or an aluminum oxide layer.

The second conductive layer MTL2 may be disposed on the gate insulating film GI. The second conductive layer MTL2 may include a single layer or a multi-layer, each layer therein including at least one selected from molybdenum (Mo), aluminum (Al), chromium (Cr), gold (Au), titanium (Ti), nickel (Ni), neodymium (Nd), and copper (Cu), or an alloy thereof.

The second conductive layer MTL2 may include or define a first gate electrode GE1 of the first transistor ST1, a second gate electrode GE2 of the second transistor ST2, a third gate electrode GE3 of the third transistor ST3, an auxiliary gate line BGL, and a second capacitor electrode CPE2 of the first capacitor C1.

The interlayer insulating film ILD may be disposed on (or to cover) the second conductive layer MTL2. The interlayer insulating film ILD may include an inorganic film, for example, a silicon nitride layer, a silicon oxynitride layer, a silicon oxide layer, a titanium oxide layer, or an aluminum oxide layer.

The second active layer ACTL2 may be disposed on the interlayer insulating film ILD. The second active layer ACTL2 may include polycrystalline silicon, single crystal silicon, low-temperature polycrystalline silicon, amorphous silicon, or an oxide semiconductor material.

The second active layer ACTL2 may include or define a third active area ACT3, a third drain electrode DE3, and a third source electrode SE3 of the third transistor ST3.

The third conductive layer MTL3 may be disposed on the interlayer insulating film ILD. In an embodiment, for example, the third conductive layer MTL3 and the second active layer ACTL2 may be disposed in (or directly on) a same layer as each other. The third conductive layer MTL3 may include a single layer or a multi-layer, each layer therein including at least one selected from molybdenum (Mo), aluminum (Al), chromium (Cr), gold (Au), titanium (Ti), nickel (Ni), neodymium (Nd), and copper (Cu), or an alloy thereof.

The third conductive layer MTL3 may include or define a gate line GL, a first connection electrode CE1, a second connection electrode CE2, a fifth connection electrode CE5, a sixth connection electrode CE6, a seventh connection electrode CE7, and an eighth connection electrode CE8.

The first passivation film PVX1 may be disposed on the third conductive layer MTL3 and the second active layer ACTL2. The first passivation film PVX1 may include an inorganic film, for example, a silicon nitride layer, a silicon oxynitride layer, a silicon oxide layer, a titanium oxide layer, or an aluminum oxide layer.

The first via film VIA1 may be disposed on the first passivation film PVX1. The first via film VIA1 may include an organic film including or made of an acryl resin, an epoxy resin, a phenolic resin, a polyamide resin, a polyimide resin, or the like.

The fourth conductive layer MTL4 may be disposed on the first via film VIA1. The fourth conductive layer MTL4 may include a single layer or a multi-layer, each layer therein including at least one selected from molybdenum (Mo), aluminum (Al), chromium (Cr), gold (Au), titanium (Ti), nickel (Ni), neodymium (Nd), and copper (Cu), or an alloy thereof.

The fourth conductive layer MTL4 may include or define a second voltage line VSL, a third connection electrode CE3, and a fourth connection electrode CE4.

The second passivation film PVX2 may be disposed on the fourth conductive layer MTL4. The second passivation film PVX2 may include an inorganic film, for example, a silicon nitride layer, a silicon oxynitride layer, a silicon oxide layer, a titanium oxide layer, or an aluminum oxide layer.

The second via film VIA2 may be disposed on the second passivation film PVX2. The second via film VIA2 may include an organic film including or made of an acryl resin, an epoxy resin, a phenolic resin, a polyamide resin, a polyimide resin, or the like.

In an embodiment, as shown in FIG. 9, the circuit layer CCL may include a first voltage line VDL, a second voltage line VSL, a data line DL, a gate line GL, an auxiliary gate line BGL, an initialization voltage line VIL, first to third transistors ST1, ST2, and ST3, and a first capacitor C1.

The first voltage line VDL may extend in the second direction DR2. The first voltage line VDL may be disposed on the left or right side of the first to third transistors ST1, ST2, and ST3 and the first capacitor C1 in a plan view. In an embodiment, for example, as illustrated in the drawings, the first voltage line VDL may be disposed on the left side of the first to third transistors ST1, ST2, and ST3 and the first capacitor C1 in a plan view, but is not limited thereto. The first voltage line VDL may be disposed in (or defined by a portion of) the first conductive layer MTL1. The first voltage line VDL may be connected to the first connection electrode CE1 through a contact hole.

The second voltage line VSL may extend in the second direction DR2. The second voltage line VSL may be disposed on the left or right side of the first to third transistors ST1, ST2, and ST3 and the first capacitor C1 in a plan view. In an embodiment, for example, as illustrated in the drawings, the second voltage line VSL may be disposed on the right side of the first to third transistors ST1, ST2, and ST3 and the first capacitor C1 in a plan view, but is not limited thereto. The second voltage line VSL may be disposed in (or defined by a portion of) the fourth conductive layer MTL4. The second voltage line VSL may be connected to a common electrode auxiliary electrode VCE through a contact hole.

The data line DL may extend in the second direction DR2. The data line DL may be disposed on the left or right side of the first to third transistors ST1, ST2, and ST3 and the first capacitor C1 in a plan view. In an embodiment, for example, as illustrated in the drawings, the data line DL may be disposed on the right side of the first to third transistors ST1, ST2, and ST3 and the first capacitor C1 in a plan view, but is not limited thereto. The data line DL may be disposed in (or defined by a portion of) the first conductive layer MTL1. The data line DL may be connected to the sixth connection electrode CE6 through a contact hole.

In some embodiments, the second voltage line VSL and the data line DL may overlap each other. Since the second voltage line VSL is disposed in (or defined by a portion of) the fourth conductive layer MTL4 and the data line DL is disposed in (or defined by a portion of) the first conductive layer MTL1, the second voltage line VSL and the data line DL may overlap each other in the third direction DR3. Accordingly, as the size of the pixel SP becomes smaller than a case where the second voltage line VSL and the data line DL are disposed not to overlap each other, pixel density may increase, and a high-resolution display device may be implemented.

The gate line GL may extend in the first direction DR1. The gate line GL may be disposed on the upper or lower side of the first to third transistors ST1, ST2, and ST3 and the first capacitor C1 in a plan view. In an embodiment, for example, as illustrated in the drawings, the gate line GL may be disposed on the lower side of the first to third transistors ST1, ST2, and ST3 and the first capacitor C1 in a plan view, but is not limited thereto. The gate line GL may be disposed in (or defined by a portion of) the third conductive layer MTL3. The gate line GL may be connected to the auxiliary gate line BGL through a contact hole.

The auxiliary gate line BGL may extend in the second direction DR2. The auxiliary gate line BGL may be disposed to cross the second transistor ST2 and third transistor ST3 in a plan view. In an embodiment, for example, as illustrated in the drawings, the auxiliary gate line BGL may be disposed between the second source electrode SE2 and the second drain electrode DE2 of the second transistor ST2 and between the third source electrode SE3 and the third drain electrode DE3 of the third transistor ST3 in a plan view. The auxiliary gate line BGL may be disposed in (or defined by a portion of) the second conductive layer MTL2. The auxiliary gate line BGL may be connected to the gate line GL through a contact hole.

A portion of the auxiliary gate line BGL may constitute the second gate electrode GE2 of the second transistor ST2 and the third gate electrode GE3 of the third transistor ST3. That is, the second gate electrode GE2 of the second transistor ST2 and the third gate electrode GE3 of the third transistor ST3 may be included in (or defined by) a same conductive line (or a same linear portion of second conductive layer MTL2), i.e., the auxiliary gate line BGL.

In the specification and drawings, the auxiliary gate line BGL and the gate line GL are described as separate components, but the auxiliary gate line BGL may be understood as a component included in the gate line GL. That is, the auxiliary gate line BGL may be understood as a portion of the gate line GL.

The initialization voltage line VIL may extend in the second direction DR2. The initialization voltage line VIL may be disposed on the left or right side of the first to third transistors ST1, ST2, and ST3 and the first capacitor C1 in a plan view. In an embodiment, for example, as illustrated in the drawings, the initialization voltage line VIL may be disposed on the right side of the first to third transistors ST1, ST2, and ST3 and the first capacitor C1 in a plan view, but is not limited thereto. The initialization voltage line VIL may be disposed in (or defined by a portion of) the first conductive layer MTL1. The initialization voltage line VIL may be connected to the fifth connection electrode CE5 through a contact hole.

The first transistor ST1 may include a first active area ACT1, a first gate electrode GE1, a first drain electrode DE1, and a first source electrode SE1.

The first active area ACT1 may be disposed in (or defined by a portion of) the first active layer ACTL1. The first active area ACT1 may overlap the first gate electrode GE1 in the third direction DR3. The first active area ACT1 may be an area where the first active layer ACTL1 is not conductive in an area overlapping the first gate electrode GE1.

The first gate electrode GE1 may be disposed (or defined by a portion of) in the second conductive layer MTL2. The first gate electrode GE1 may be connected to the second capacitor electrode CPE2 of the first capacitor C1. In an embodiment, the first gate electrode GE1 may be an electrode integrated with the second capacitor electrode CPE2 of the first capacitor C1. In an embodiment, for example, the first gate electrode GE1 may be a portion of the second capacitor electrode CPE2 of the first capacitor C1. The first gate electrode GE1 may be connected to the second source electrode SE2 of the second transistor ST2 through the second capacitor electrode CPE2 of the first capacitor C1 and the seventh connection electrode CE7.

An embodiment where the first transistor ST1 has a top gate structure in which the first gate electrode GE1 is disposed above the first active area ACT1 is illustrated in the drawing, but the first transistor ST1 is not limited thereto. In another embodiment, for example, the first transistor ST1 may have a bottom gate structure in which the first gate electrode GE1 is disposed below the first active area ACT1. In another embodiment, for example, the first transistor ST1 may also have a double gate structure in which the first gate electrode GE1 is disposed both above and below the first active area ACT1.

The first drain electrode DE1 and the first source electrode SE1 may be disposed in (or defined by a portion of) the first active layer ACTL1. The first drain electrode DE1 and the first source electrode SE1 may be formed by heat treating and conducting the first active layer ACTL1. The first drain electrode DE1 and the first source electrode SE1 may be conductors of a P-type semiconductor or an N-type semiconductor, but are not limited thereto.

The first drain electrode DE1 may be electrically connected to the first voltage line VDL. In an embodiment, for example, the first drain electrode DE1 may be connected to the first voltage line VDL through the first connection electrode CE1. Accordingly, the first drain electrode DE may receive the first driving voltage from the first voltage line VDL.

The first source electrode SE1 may be electrically connected to the pixel electrode PXE of the light emitting element ED. In an embodiment, for example, the first source electrode SE1 may be connected to the light emitting element ED through the second connection electrode CE2 and the third connection electrode CE3. Accordingly, the first source electrode SE1 may supply the driving current to the light emitting element ED.

The first source electrode SE1 may be electrically connected to the first capacitor C1. In an embodiment, for example, the first source electrode SE1 may be connected to the first capacitor electrode CPE1 of the first capacitor C1 through the eighth connection electrode CE8.

The second transistor ST2 may include a second active area ACT2, a second gate electrode GE2, a second drain electrode DE2, and a second source electrode SE2.

The second active area ACT2 may be disposed in (or defined by a portion of) the first active layer ACTL1. The second active area ACT2 may overlap the second gate electrode GE2 in the third direction DR3. The second active area ACT2 may be an area where the first active layer ACTL1 is not conductive in an area overlapping the second gate electrode GE2.

The second gate electrode GE2 may be disposed in (or defined by a portion of) the second conductive layer MTL2. The second gate electrode GE2 may be connected to the auxiliary gate line BGL. In an embodiment, the second gate electrode GE2 may be integrated with the auxiliary gate line BGL. In an embodiment, for example, the second gate electrode GE2 may be a portion of the auxiliary gate line BGL. The second gate electrode GE2 may be connected to the gate line GL through the auxiliary gate line BGL.

In an embodiment, the second transistor ST2 may have a top gate structure in which the second gate electrode GE2 is disposed above the second active area ACT2.

The second drain electrode DE2 and the second source electrode SE2 may be disposed in (or defined by a portion of) the first active layer ACTL1. The second drain electrode DE2 and the second source electrode SE2 may be formed by heat treating and conducting the first active layer ACTL1. The second drain electrode DE2 and the second source electrode SE2 may be conductors of a P-type semiconductor or an N-type semiconductor, but are not limited thereto.

The second drain electrode DE2 may be electrically connected to the data line DL. In an embodiment, for example, the second drain electrode DE2 may be connected to the data line DL through the sixth connection electrode CE6. Accordingly, the second drain electrode DE2 may receive the data voltage from the data line DL.

The second source electrode SE2 may be electrically connected to the second capacitor electrode CPE2 of the first capacitor C1. In an embodiment, for example, the second source electrode SE2 may be connected to the second capacitor electrode CPE2 of the first capacitor C1 through the seventh connection electrode CE7.

The second source electrode SE2 may be electrically connected to the first gate electrode GE1 of the first transistor ST1. In an embodiment, for example, the second source electrode SE2 may be connected to the first gate electrode GE1 of the first transistor ST1 through the seventh connection electrode CE7 and the second capacitor electrode CPE2 of the first capacitor C1. Accordingly, the second source electrode SE2 may supply the data voltage to the first gate electrode GE1 of the first transistor ST1.

The third transistor ST3 may include a third active area ACT3, a third gate electrode GE3, a third drain electrode DE3, and a third source electrode SE3.

The third active area ACT3 may be disposed in (or defined by a portion of) the second active layer ACTL2. The third active area ACT3 may overlap the third gate electrode GE3 in the third direction DR3. The third active area ACT3 may be an area where the second active layer ACTL2 is not conductive in an area overlapping the third gate electrode GE3.

The third gate electrode GE3 may be disposed in (or defined by a portion of) the second conductive layer MTL2. The third gate electrode GE3 may be connected to the auxiliary gate line BGL. In an embodiment, the third gate electrode GE3 may be integrated with the auxiliary gate line BGL. In an embodiment, for example, the third gate electrode GE3 may be a portion of the auxiliary gate line BGL. The third gate electrode GE3 may be connected to the gate line GL through the auxiliary gate line BGL.

In an embodiment, the third transistor ST3 may have a bottom gate structure in which the third gate electrode GE3 is disposed below the third active area ACT3.

The third drain electrode DE3 and the third source electrode SE3 may be disposed in (or defined by a portion of) the second active layer ACTL2. The third drain electrode DE3 and the third source electrode SE3 may be formed by heat treating and conducting the second active layer ACTL2. The third drain electrode DE3 and the third source electrode SE3 may be conductors of a P-type semiconductor or an N-type semiconductor, but are not limited thereto.

The third drain electrode DE3 may be electrically connected to the first source electrode SE1 of the first transistor ST1. In an embodiment, for example, the third drain electrode DE3 may be connected to the first source electrode SE1 of the first transistor ST1 through the third connection electrode CE3 and the second connection electrode CE2. Accordingly, the third drain electrode DE3 may supply the initialization voltage to the first source electrode SE1 of the first transistor ST1, and may receive the sensing voltage from the first source electrode SE1 of the first transistor ST1.

The third drain electrode DE3 may be connected to the first capacitor electrode CPE1 of the first capacitor C1. In an embodiment, for example, the third drain electrode DE3 may be connected to the first capacitor electrode CPE1 of the first capacitor C1 through the third connection electrode CE3, the second connection electrode CE2, the first source electrode SE1 of the first transistor ST1, and the eighth connection electrode CE8.

The third source electrode SE3 may be connected to the initialization voltage line VIL. In an embodiment, for example, the third source electrode SE3 may be connected to the initialization voltage line VIL through the fourth connection electrode CE4 and the fifth connection electrode CE5. Accordingly, the third source electrode SE3 may receive the initialization voltage from the initialization voltage line VIL and supply the sensing voltage to the initialization voltage line VIL.

The first capacitor C1 may include the first capacitor electrode CPE1 and the second capacitor electrode CPE2.

The first capacitor electrode CPE1 may be disposed in (or defined by a portion of) the first conductive layer MTL1. The first capacitor electrode CPE1 may be connected to the first source electrode SE1 of the first transistor ST1 through the eighth connection electrode CE8. The first capacitor electrode CPE1 may be connected to the third drain electrode DE3 of the third transistor ST3 through the eighth connection electrode CE8, the first source electrode SE1 of the first transistor ST1, the second connection electrode CE2, and the third connection electrode CE3.

The second capacitor electrode CPE2 may be disposed in (or defined by a portion of) the second conductive layer MTL2. The second capacitor electrode CPE2 may be connected to the first gate electrode GE1 of the first transistor ST1. In an embodiment, as described above, a portion of the second capacitor electrode CPE2 may constitute the first gate electrode GE1 of the first transistor ST1. The second capacitor electrode CPE2 may be connected to the second source electrode SE2 of the second transistor ST2 through the seventh connection electrode CE7.

The light emitting element layer EML may be disposed on the circuit layer CCL. The light emitting element layer EML may include a fifth conductive layer MTL5, a pixel defining film PDL and a light emitting element ED. The light emitting element ED may include a pixel electrode PXE, a light emitting layer LEL, and a common electrode CME.

The pixel defining film PDL, the light emitting element ED, the pixel electrode PXE, the light emitting layer LEL, and the common electrode CME are substantially the same as those described above with reference to FIG. 7, and any repetitive detailed descriptions thereof will thus be omitted.

The fifth conductive layer MTL5 may be disposed on the circuit layer CCL. In an embodiment, for example, the fifth conductive layer MTL5 may be disposed on the second via film VIA2. The fifth conductive layer MTL5 may have a stacked film structure in which a material layer having a high work function, such as indium tin oxide (ITO), indium zinc oxide (IZO), zinc oxide (ZnO), or indium oxide (In₂O₃) and a reflective material layer such as silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or mixtures thereof are stacked. The fifth conductive layer MTL5 may include a pixel electrode PXE and a common electrode auxiliary electrode VCE.

The common electrode auxiliary electrode VCE may be disposed in (or defined by a portion of) the fifth conductive layer MTL5. The common electrode auxiliary electrode VCE may be connected to the second voltage line VSL through a contact hole. The common electrode auxiliary electrode VCE may receive the second driving voltage from the second voltage line VSL.

The common electrode auxiliary electrode VCE may be connected to the common electrode CME through a contact hole formed through a laser drilling process. In an embodiment, for example, the contact hole formed through the laser drilling process may penetrate through the light emitting layer LEL and the pixel defining film PDL. The common electrode CME may receive the second driving voltage from the second voltage line VSL through the common electrode auxiliary electrode VCE.

In the display device 10 according to an embodiment, the second active area ACT2 of the second transistor ST2 and the third active area ACT3 of the third transistor ST3 may be disposed in different layers. In an embodiment, for example, the second active area ACT2 of the second transistor ST2 may be disposed in (or defined by a portion of) the first active layer ACTL1, and the third active area ACT3 of the third transistor ST3 may be disposed in (or defined by a portion of) the second active layer ACTL2.

In the display device 10 according to an embodiment, the second active area ACT2 of the second transistor ST2 and the third active area ACT3 of the third transistor ST3 may be positioned opposite to each other with the second conductive layer MTL2, on which the auxiliary gate line BGL or the third gate electrode GE3 is disposed, interposed therebetween. In an embodiment, for example, the second active area ACT2 of the second transistor ST2 may be disposed under the second conductive layer MTL2, and the third active area ACT3 of the third transistor ST3 may be disposed above the second conductive layer MTL2. Accordingly, the second transistor ST2 may have a top gate structure, and the third transistor ST3 may have a bottom gate structure.

In the display device 10 according to an embodiment, the second gate electrode GE2 of the second transistor ST2 and the third gate electrode GE3 of the third transistor ST3 may be included in or defined by a same line. In an embodiment, for example, the second gate electrode GE2 of the second transistor ST2 and the third gate electrode GE3 of the third transistor ST3 may be each included in (or defined by a portion of) the auxiliary gate line BGL. In an embodiment, the second gate electrode GE2 of the second transistor ST2 and the third gate electrode GE3 of the third transistor ST3 may be each positioned in different portions of the auxiliary gate line BGL.

An embodiment where the second gate electrode GE2 of the second transistor ST2 and the third gate electrode GE3 of the third transistor ST3 are portions of the auxiliary gate line BGL is illustrated in the drawing, but the disclosure is not limited thereto. In another embodiment, for example, the second gate electrode GE2 of the second transistor ST2 and the third gate electrode GE3 of the third transistor ST3 may be each included in (or defined by a portion of) the gate line GL. In such an embodiment, the second gate electrode GE2 of the second transistor ST2 and the third gate electrode GE3 of the third transistor ST3 may be each positioned in different portions of the gate line GL.

The second transistor ST2 and the third transistor ST3 may be applied with a first gate voltage (or a scan voltage) and a second gate voltage (or a sensing voltage), respectively, through the auxiliary gate line BGL (or the gate line GL), which is a common line. That is, the first gate voltage and the second gate voltage respectively applied to the second transistor ST2 and the third transistor ST3 may be applied through the auxiliary gate line BGL (or the gate line GL), which is one common line. One common line refers to a line that is electrically connected and has a same potential even though it is physically composed of two or more electrodes. In an embodiment, for example, as described above, the gate line GL and the auxiliary gate line BGL may be understood as belonging to one common line electrically connected through the contact hole.

Accordingly, in such an embodiment, the line for applying the first gate voltage to the second transistor ST2 and the line for applying the second gate voltage to the third transistor ST3 are not separately provided, such that the size of the pixel SP becomes smaller, thereby increasing pixel density, and a high-resolution display device may be implemented.

In some embodiments, the first gate voltage and the second gate voltage may be applied to the gate line GL from the first driver 120 at different timings. Accordingly, the first gate voltage and the second gate voltage may be effectively prevented from interfering with each other.

In the display device 10 according to an embodiment, the second transistor ST2 and the third transistor ST3 may be disposed to be spaced apart from each other. The second transistor ST2 and third transistor ST3 may not overlap each other in the third direction DR3. In an embodiment, for example, as illustrated in FIG. 9, the second transistor ST2 and the third transistor ST3 may be disposed to be spaced apart from each other in the second direction DR2. The second transistor ST2 may be disposed on one side in the second direction DR2 compared to the third transistor ST3, and the third transistor ST3 may be disposed on the other side in the second direction DR2 compared to the second transistor ST2.

In an embodiment, extension directions of the second transistor ST2 and the third transistor ST3 may be different from an extension direction of at least one of the auxiliary gate line BGL, the first voltage line VDL, the second voltage line VSL, the data line DL, and the initialization voltage line VIL. In an embodiment, for example, the second drain electrode DE2, the second active area ACT2, and the second source electrode SE2 of the second transistor ST2 may be disposed to be parallel in the first direction DR1, and the third drain electrode DE3, the third active area ACT3, and the third source electrode SE3 of the third transistor ST3 may be disposed to be parallel in the first direction DR1.

Hereinafter, other embodiments of the display device will be described. In description of the following embodiments, the same components as those of the above-described embodiment will be denoted by the same reference numerals, and any repetitive detailed description thereof will be omitted or simplified and differences will be mainly described.

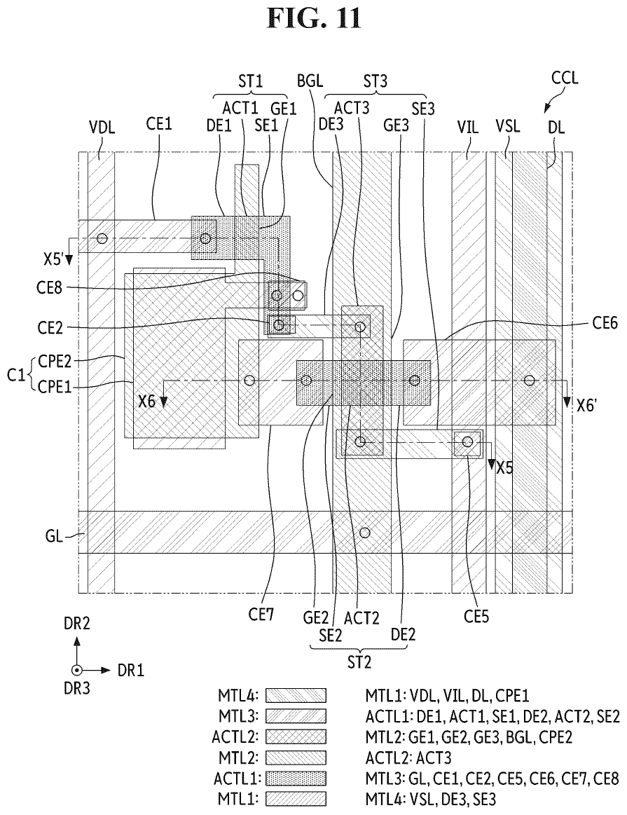

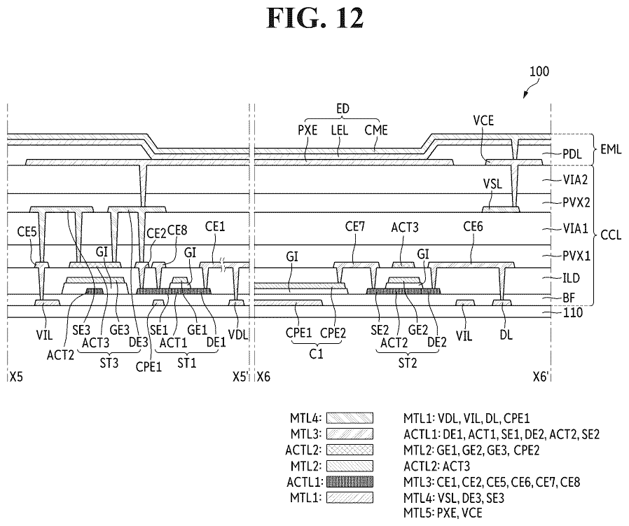

FIG. 11 is a plan view illustrating a circuit layer according to another embodiment. FIG. 12 is a cross-sectional view taken along lines X5-X5′ and X6-X6′ of FIG. 11.

The display device 10 10 according to an embodiment of FIGS. 11 and 12 is substantially the same as the display device 10 according to the embodiment described above with reference to FIGS. 9 and 10 except that the second transistor ST2 and the third transistor ST3 overlap each other in a plan view. Hereinafter, a display device 10 according to an embodiment of FIGS. 11 and 12 will be described, focusing on differences from the display device 10 according to the embodiment described above with reference to FIGS. 9 and 10.

In an embodiment, as shown in FIGS. 11 and 12, the second active layer ACTL2 may include or define the third active area ACT3 of the third transistor ST3. The fourth conductive layer MTL4 may include or define the second voltage line VSL, the third drain electrode DE3 of the third transistor ST3, and the third source electrode SE3 of the third transistor ST3.

In the display device 10 according to an embodiment, the third drain electrode DE3 of the third transistor ST3 and the third source electrode SE3 of the third transistor ST3 may be disposed in (or defined by a portion of) the fourth conductive layer MTL4. In such an embodiment of the display device 10, the third connection electrode CE3 and the fourth connection electrode CE4 of the display device 10 described above with reference to FIGS. 9 10 may be omitted.

The first source electrode SE1 of the first transistor ST1 may be electrically connected to the pixel electrode PXE of the light emitting element ED. In an embodiment, for example, the first source electrode SE1 may be connected to the light emitting element ED through the second connection electrode CE2 and the third drain electrode DE3 of the third transistor ST3. Accordingly, the first source electrode SE1 may supply the driving current to the light emitting element ED.

The third drain electrode DE3 and the third source electrode SE3 may be disposed in (or defined by a portion of) the fourth conductive layer MTL4. The third drain electrode DE3 and the third source electrode SE3 may be connected to the third active area ACT3 disposed in (or defined by a portion of) the second active layer ACTL2 through a contact hole.

The third drain electrode DE3 may be electrically connected to the first source electrode SE1 of the first transistor ST1. In an embodiment, for example, the third drain electrode DE3 may be connected to the first source electrode SE1 of the first transistor ST1 through the second connection electrode CE2. Accordingly, the third drain electrode DE3 may supply the initialization voltage to the first source electrode SE1 of the first transistor ST1, and may receive the sensing voltage from the first source electrode SE1 of the first transistor ST1.

The third drain electrode DE3 may be connected to the first capacitor electrode CPE1 of the first capacitor C1. In an embodiment, for example, the third drain electrode DE3 may be connected to the first capacitor electrode CPE1 of the first capacitor C1 through the second connection electrode CE2, the first source electrode SE1 of the first transistor ST1, and the eighth electrode CE8.

The third source electrode SE3 may be connected to the initialization voltage line VIL. In an embodiment, for example, the third source electrode SE3 may be connected to the initialization voltage line VIL through the fifth connection electrode CE5. Accordingly, the third source electrode SE3 may receive the initialization voltage from the initialization voltage line VIL and supply the sensing voltage to the initialization voltage line VIL.

The first capacitor electrode CPE1 may be disposed in (or defined by a portion of) the first conductive layer MTL1. The first capacitor electrode CPE1 may be connected to the first source electrode SE1 of the first transistor ST1 through the eighth connection electrode CE8. The first capacitor electrode CPE1 may be connected to the third drain electrode DE3 of the third transistor ST3 through the eighth connection electrode CE8, the first source electrode SE1 of the first transistor ST1, and the second connection electrode CE2.

In the display device 10 according to an embodiment, the second transistor ST2 and the third transistor ST3 may be disposed to overlap each other. In an embodiment, for example, as illustrated in FIG. 11, the third active area ACT3 of the third transistor ST3 may overlap the second active area ACT2 of the second transistor ST2 in the third direction DR3.

The second gate electrode GE2 of the second transistor ST2 and the third gate electrode GE3 of the third transistor ST3 may at least partially overlap each other in the third direction DR3.

In an embodiment, as shown in FIG. 11, the extension directions of the second transistor ST2 and the third transistor ST3 may be different from each other. The extension direction of the second transistor ST2 may be different from an extension direction of at least one selected from the auxiliary gate line BGL, the first voltage line VDL, the second voltage line VSL, the data line DL, and the initialization voltage line VIL, and the extension direction of the third transistor ST3 may be the same as the extension direction of at least one of the auxiliary gate line BGL, the first voltage line VDL, the second voltage line VSL, the data line DL, and the initialization voltage line VIL.

In an embodiment, for example, the second drain electrode DE2, the second active area ACT2, and the second source electrode SE2 of the second transistor ST2 may be disposed to be parallel in the first direction DR1 in a plan view. The third drain electrode DE3, the third active area ACT3, and the third source electrode SE3 of the third transistor ST3 may be disposed to be parallel in the second direction DR2 in the plan view. The second active area ACT2 of the second transistor ST2 may extend in the first direction DR1, and the third active area ACT3 of the third transistor ST3 may extend in the second direction DR2 in the plan view.

However, the disclosure is not limited thereto, and the extension direction of the second transistor ST2 may be the same as the extension direction of at least one of the auxiliary gate line BGL, the first voltage line VDL, the second voltage line VSL, the data line DL, and the initialization voltage line VIL, and the extension direction of the third transistor ST3 may be different from the extension direction of at least one of the auxiliary gate line BGL, the first voltage line VDL, the second voltage line VSL, the data line DL, and the initialization voltage line VIL.

In the display device 10 according to an embodiment, as the second transistor ST2 and the third transistor ST3 are disposed to overlap each other, the size of the pixel SP may be reduced, thereby increasing pixel density, and a high-resolution display device may be implemented.

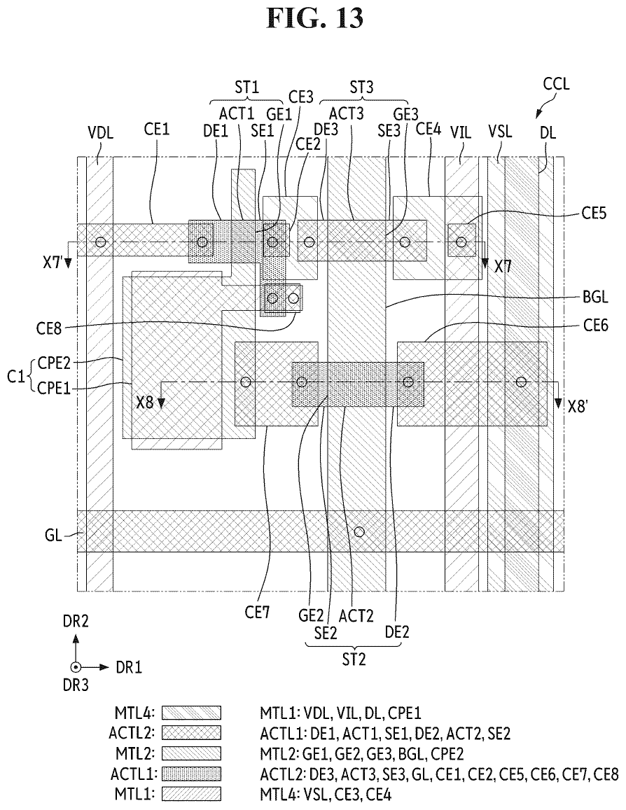

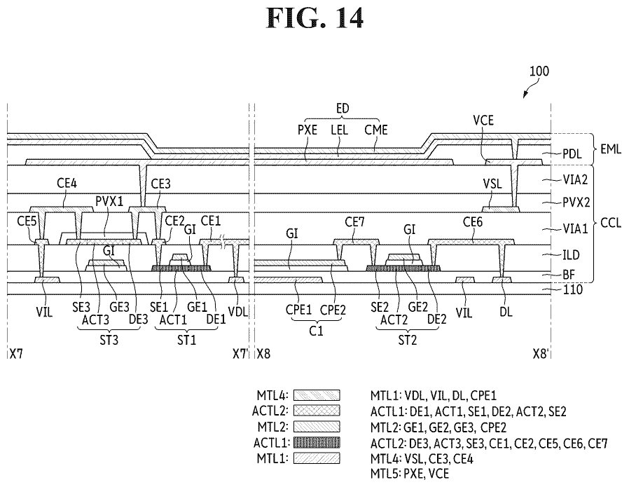

FIG. 13 is a plan view illustrating a circuit layer according to still another embodiment. FIG. 14 is a cross-sectional view taken along lines X7-X7′ and X8-X8′ of FIG. 13.

The display device 10 according to an embodiment of FIGS. 13 and 14 is substantially the same as the display device 10 according to the embodiment described above with reference to FIGS. 9 and 10 except that the third conductive layer MTL3 is omitted. Hereinafter, a display device 10 according to an embodiment of FIGS. 13 and 14 will be described, focusing on differences from the display device 10 according to the embodiment described with reference to FIGS. 9 and 10.

In an embodiment, as shown in FIGS. 13 and 14, the circuit layer CCL may include or define a first conductive layer MTL1, a buffer film BF, a first active layer ACTL1, a gate insulating film G1, a second conductive layer MTL2, an interlayer insulating film ILD, a second active layer ACTL2, a first passivation film PVX1, a first via film VIA1, a fourth conductive layer MTL4, a second passivation film PVX2, and a second via film VIA2.

The second active layer ACTL2 may include or define the third active area ACT3, the third drain electrode DE3, and the third source electrode SE3 of the third transistor ST3, the gate line GL, the first connection electrode CE1, the second connection electrode CE2, the fifth connection electrode CE5, the sixth connection electrode CE6, the seventh connection electrode CE7, and the eighth connection electrode CE8.

In the display device 10 according to an embodiment described with reference to FIGS. 9 and 10, the gate line GL, the first connection electrode CE1, the second connection electrode CE2, the fifth connection electrode CE5, the sixth connection electrode CE6, the seventh connection electrode CE7, and the eighth connection electrode CE8 are disposed in (or defined by a portion of) the third conductive layer MTL3. In another embodiment, as shown in FIGS. 13 and 14, the gate line GL, the first connection electrode CE1, the second connection electrode CE2, the fifth connection electrode CE5, the sixth connection electrode CE6, the seventh connection electrode CE7, and the eighth connection electrode CE8 may be disposed in (or defined by a portion of) the second active layer ACTL2.

The gate line GL, the first connection electrode CE1, the second connection electrode CE2, the fifth connection electrode CE5, the sixth connection electrode CE6, the seventh connection electrode CE7, and the eighth connection electrode CE8 disposed in (or defined by a portion of) the second active layer ACTL2 may be formed by heat treating and conducting the second active layer ACTL2.

The first passivation film PVX1 may be disposed on the second active layer ACTL2. In some embodiments, the passivation film PVX1 may be disposed to cover the third active area ACT3, the third drain electrode DE3, and the third source electrode SE3 among the components disposed in (or defined by a portion of) the second active layer ACTL2. In an embodiment, for example, the passivation film PVX1 may cover only the third active area ACT3, the third drain electrode DE3, and the third source electrode SE3 among the components disposed in (or defined by a portion of) the second active layer ACTL2, and may not cover the first connection electrode CE1, the second connection electrode CE2, the fifth connection electrode CE5, the sixth connection electrode CE6, the seventh connection electrode CE7, and the eighth connection electrode CE8 in a plan view. The first passivation film PVX1 may not overlap the first connection electrode CE1, the second connection electrode CE2, the fifth connection electrode CE5, the sixth connection electrode CE6, the seventh connection electrode CE7, and the eighth connection electrode CE8 in the third direction DR3. Accordingly, a thickness of the first passivation film PVX1 may be reduced.

The first via film VIA1 may be disposed on the second active layer ACTL2 and the first passivation film PVX1. The first via film VIA1 may cover the first passivation film PVX1 and the second active layer ACTL2 that is not covered by the first passivation film PVX1.

In such an embodiment, as described above, the display device 10 does not include the third conductive layer MTL3, such that the number of manufacturing process steps and masks for the display device 10 may be reduced, thereby reducing manufacturing process time and cost. In addition, the thickness of the first passivation film PVX1 may be reduced, thereby minimizing a thickness of the display device 10.

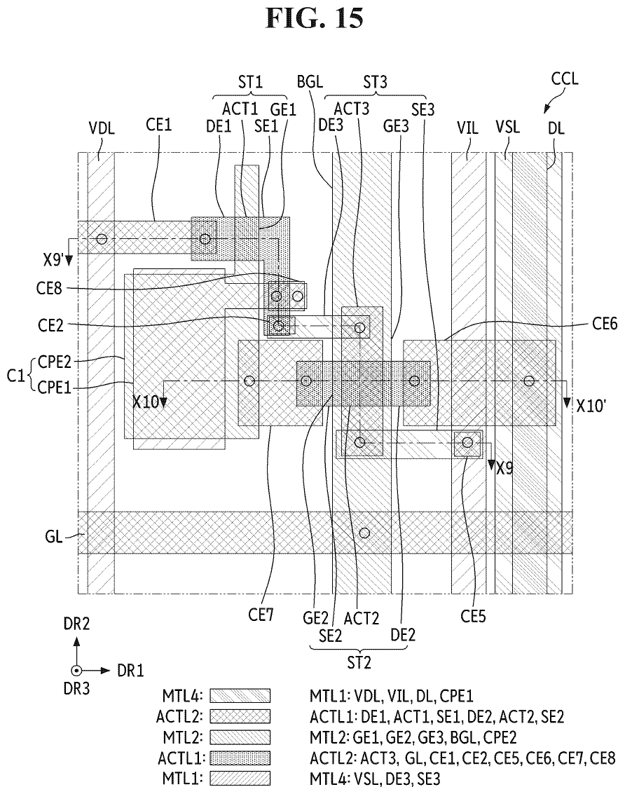

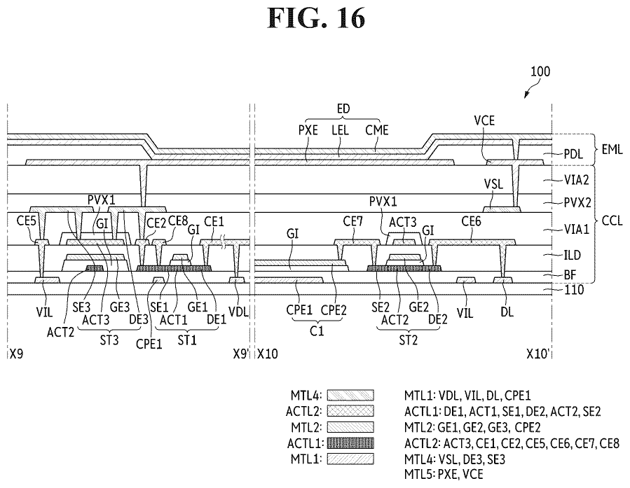

FIG. 15 is a plan view illustrating a circuit layer according to still another embodiment. FIG. 16 is a cross-sectional view taken along lines X9-X9′ and X10-X10′ of FIG. 15.

The display device 10 according to an embodiment of FIGS. 15 and 16 is substantially the same as the display device 10 according to the embodiment described above with reference to FIGS. 11 and 12 except that the third conductive layer MTL3 is omitted. Hereinafter, a display device 10 according to an embodiment of FIGS. 15 and 16 will be described, focusing on differences from the display device 10 according to the embodiment described above with reference to FIGS. 11 and 12.

In an embodiment, as shown in FIGS. 15 and 16,, the circuit layer CCL may include or define a first conductive layer MTL1, a buffer film BF, a first active layer ACTL1, a gate insulating film G1, a second conductive layer MTL2, an interlayer insulating film ILD, a second active layer ACTL2, a first passivation film PVX1, a first via film VIA1, a fourth conductive layer MTL4, a second passivation film PVX2, and a second via film VIA2.

The second active layer ACTL2 may include or define the third active area ACT3, of the third transistor ST3, the gate line GL, the first connection electrode CE1, the second connection electrode CE2, the fifth connection electrode CE5, the sixth connection electrode CE6, the seventh connection electrode CE7, and the eighth connection electrode CE8.

In the display device 10 according to an embodiment described with reference to FIGS. 11 and 12, the gate line GL, the first connection electrode CE1, the second connection electrode CE2, the fifth connection electrode CE5, the sixth connection electrode CE6, the seventh connection electrode CE7, and the eighth connection electrode CE8 are disposed in (or defined by a portion of) the third conductive layer MTL3. In another embodiment, as shown in FIGS. 15 and 16, the gate line GL, the first connection electrode CE1, the second connection electrode CE2, the fifth connection electrode CE5, the sixth connection electrode CE6, the seventh connection electrode CE7, and the eighth connection electrode CE8 may be disposed in (or defined by a portion of) the second active layer ACTL2.

The gate line GL, the first connection electrode CE1, the second connection electrode CE2, the fifth connection electrode CE5, the sixth connection electrode CE6, the seventh connection electrode CE7, and the eighth connection electrode CE8 disposed in (or defined by portions of) the second active layer ACTL2 may be formed by heat treating and conducting the second active layer ACTL2.

The first passivation film PVX1 may be disposed on the second active layer ACTL2. In some embodiments, the first passivation film PVX1 may be disposed to cover the third active area ACT3 among the components disposed in (or defined by a portion of) the second active layer ACTL2. In an embodiment, for example, the passivation film PVX1 may cover only the third active area ACT3 among the components disposed in (or defined by a portion of) the second active layer ACTL2, and may not cover the first connection electrode CE1, the second connection electrode CE2, the fifth connection electrode CE5, the sixth connection electrode CE6, the seventh connection electrode CE7, and the eighth connection electrode CE8 in a plan view. The first passivation film PVX1 may not overlap the first connection electrode CE1, the second connection electrode CE2, the fifth connection electrode CE5, the sixth connection electrode CE6, the seventh connection electrode CE7, and the eighth connection electrode CE8 in the third direction DR3. Accordingly, a thickness of the first passivation film PVX1 may be reduced.

The first via film VIA1 may be disposed on the second active layer ACTL2 and the first passivation film PVX1. The first via film VIA1 may cover the first passivation film PVX1 and a portion of the second active layer ACTL2 that is not covered by the first passivation film PVX1 in a plan view.

In such an embodiment, the display device 10 does not include the third metal layer MTL3, such that the number of manufacturing process steps and masks for the display device 10 may be reduced, thereby reducing manufacturing process time and cost. In addition, the thickness of the first passivation film PVX1 may be reduced, thereby minimizing a thickness of the display device 10.

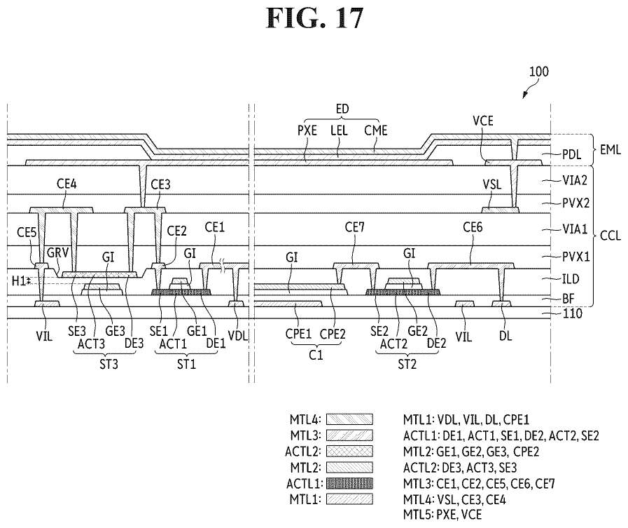

FIG. 17 is a cross-sectional view illustrating a display substrate according to still another embodiment.

The display device 10 according to an embodiment of FIG. 17 is substantially the same as the display device 10 according to the embodiments described above with reference to FIGS. 9 to 16 except for a groove GRV of the interlayer insulating film ILD.

In an embodiment, as shown in FIG. 17, the interlayer insulating film ILD may include or define a groove GRV. The groove GRV may be a groove recessed from an upper surface to a lower surface of the interlayer insulating film ILD. The upper surface of the interlayer insulating film ILD positioned within the groove GRV may be positioned lower than the upper surface of the interlayer insulating film ILD in which the groove GRV is not disposed. In some embodiments, the groove GRV may be formed using a half-tone mask or slit mask in a process of forming the interlayer insulating film ILD.

At least a portion of the second active layer ACTL2 may be disposed in the groove GRV. In an embodiment, for example, as illustrated in FIG. 17, the third active area ACT3, the third drain electrode DE3, and the third source electrode SE3 disposed in (or defined by a portion of) the second active layer ACTL2 may be disposed in the groove GRV. Accordingly, a first distance H1 (e.g., a distance in the third direction DR3) between the third active area ACT3 and the third gate electrode GE3 may be decreased.

In the display device 10 according to an embodiment, by disposing the third active layer ACTL3 in the groove GRV to reduce the first distance H1 between the third active area ACT3 and the third gate electrode GE3, sensitivity of the gate voltage that determines the turn-on of the drain-source current (driving current) may be increased.

In some embodiments, a thickness of the interlayer insulating film ILD (e.g., a length in the third direction DR3) may be greater than a thickness of the gate insulating film GI (e.g., a length in the third direction DR3). In the display device 10 according to an embodiment, by reducing the first distance H1 to increase the sensitivity of the gate voltage, the sensitivity of the gate voltage of the third transistor ST3, which has the bottom gate structure, may be adjusted to a similar level as that of the second transistor ST2, which has the top gate structure.

An embodiment where the second active layer ACTL2 disposed in the groove GRV corresponds to the second active layer ACTL2 shown in FIG. 9 is illustrated in the drawing as an example, but the disclosure is not limited thereto. In another embodiment, for example, the second active layer ACTL2 disposed in the groove GRV may correspond to the second active layer ACTL2 shown in FIG. 11. In such an embodiment, the third active area ACT3 disposed in (or defined by a portion of) the second active layer ACTL may be disposed in the groove GRV.

In another embodiment, for example, the second active layer ACTL2 disposed in the groove GRV may correspond to the second active layer ACTL2 shown in FIG. 13 or 15. In some embodiments corresponding to those described with reference to FIGS. 13 to 16, only the second active area ACT2 and the third active area ACT3, excluding the connection electrodes CE1, CE2, CE5, CE6, CE7, and CE8, among the components disposed in (or defined by portions of) the second active layer ACTL2, may also be disposed in the groove GRV. The connection electrodes CE1, CE2, CE5, CE6, CE7, and CE8 among the components disposed in (or defined by portions of) the second active layer ACTL2 may be disposed on the upper surface of the interlayer insulating film ILD on which the groove GRV is not disposed, and the second active area ACT2 and the third active area ACT3 may be disposed in the groove GRV.

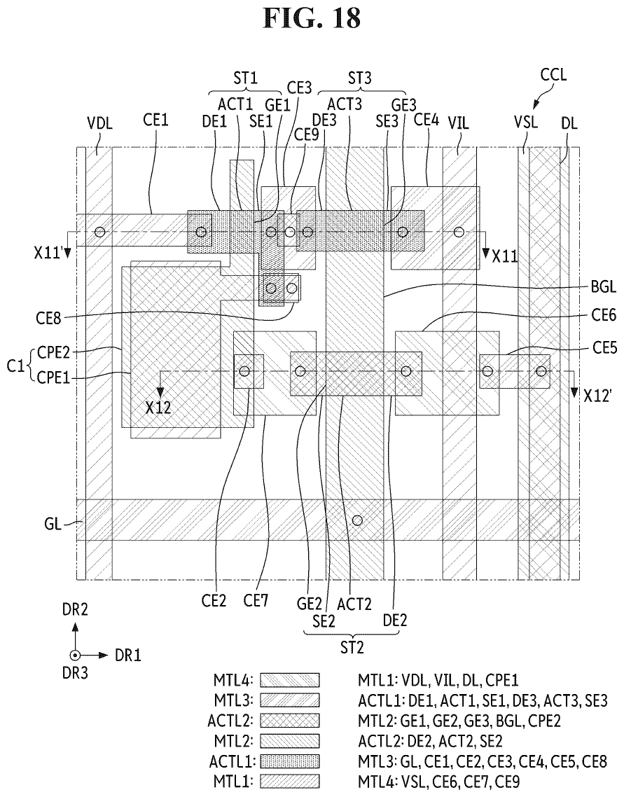

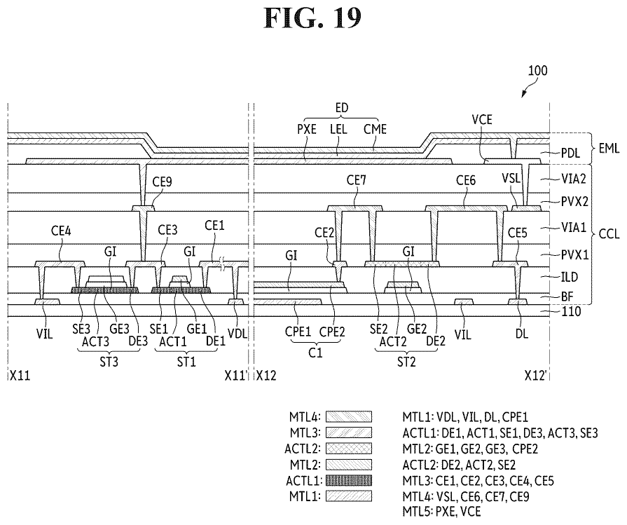

FIG. 18 is a plan view illustrating a circuit layer according to still another embodiment. FIG. 19 is a cross-sectional view taken along lines X11-X11′ and X12-X12′ of FIG. 18.

The display device 10 according to the embodiment of FIGS. 18 and 19 is substantially the same as the display device 10 according to the embodiments described above with reference to FIGS. 9 to 17 except that the second transistor ST2 has a bottom gate structure and the third transistor ST3 has a bottom gate structure. Hereinafter, differences from the display device 10 according to the embodiment described above with reference to FIGS. 9 to 17 will be mainly described.

In an embodiment, as shown in FIGS. 18 and 19, the first active layer ACTL1 may include or define a first active area ACT1, a first drain electrode DE1, and a first source electrode SE1 of the first transistor ST1, and a third active area ACT3, a third drain electrode DE3, and a third source electrode SE3 of the third transistor ST3.

The second active layer ACTL2 may include or define a second active area ACT2, a second drain electrode DE2, and a second source electrode SE2 of the second transistor ST2.

The third conductive layer MTL3 may include or define a gate line GL, a first connection electrode CE1, a second connection electrode CE2, a third connection electrode CE3, a fourth connection electrode CE4, a fifth connection electrode CE5, and an eighth connection electrode CE8.

The fourth conductive layer MTL4 may include or define a second voltage line VSL, a sixth connection electrode CE6, a seventh connection electrode CE7, and a ninth connection electrode CE9.

The data line DL may be connected to the fifth connection electrode CE5 through a contact hole. The data line DL may be connected to the sixth connection electrode CE6 through the fifth connection electrode CE5.

The initialization voltage line VIL may be connected to the fourth connection electrode CE4 through a contact hole.

The first gate electrode GE1 may be connected to the second source electrode SE2 of the second transistor ST2 through the second capacitor electrode CPE2 of the first capacitor C1, the second connection electrode CE2, and the seventh connection electrode CE7.

The first source electrode SE1 may be electrically connected to the pixel electrode PXE of the light emitting element ED. In an embodiment, for example, the first source electrode SE1 may be connected to the light emitting element ED through the third connection electrode CE3 and the ninth connection electrode CE9. Accordingly, the first source electrode SE1 may supply the driving current to the light emitting element ED.

The second active area ACT2 may be disposed in (or defined by a portion of) the second active layer ACTL2. The second active area ACT2 may overlap the second gate electrode GE2 in the third direction DR3. The second active area ACT2 may be an area where the second active layer ACTL2 is not conductive in an area overlapping the second gate electrode GE2. In an embodiment, the second transistor ST2 may have a bottom gate structure in which the second gate electrode GE2 is disposed below the second active area ACT2.

The second drain electrode DE2 and the second source electrode SE2 may be disposed in (or defined by portions of) the second active layer ACTL2. The second drain electrode DE2 and the second source electrode SE2 may be formed by heat treating and conducting the second active layer ACTL2. The second drain electrode DE2 and the second source electrode SE2 may be conductors of a P-type semiconductor or an N-type semiconductor, but are not limited thereto.

The second drain electrode DE2 may be electrically connected to the data line DL. In an embodiment, for example, the second drain electrode DE2 may be connected to the data line DL through the sixth connection electrode CE6 and the fifth connection electrode CE5. Accordingly, the second drain electrode DE2 may receive the data voltage from the data line DL.

The second source electrode SE2 may be electrically connected to the second capacitor electrode CPE2 of the first capacitor C1. In an embodiment, for example, the second source electrode SE2 may be connected to the second capacitor electrode CPE2 of the first capacitor C1 through the second connection electrode CE2 and the seventh connection electrode CE7.

The second source electrode SE2 may be electrically connected to the first gate electrode GE1 of the first transistor ST1. In an embodiment, for example, the second source electrode SE2 may be connected to the first gate electrode GE1 of the first transistor ST1 through the seventh connection electrode CE7, the second connection electrode CE2, and the second capacitor electrode CPE2 of the first capacitor C1. Accordingly, the second source electrode SE2 may supply the data voltage to the first gate electrode GE1 of the first transistor ST1.

The third active area ACT3 may be disposed in (or defined by a portion of) the first active layer ACTL1. The third active area ACT3 may overlap the third gate electrode GE3 in the third direction DR3. The third active area ACT3 may be an area where the first active layer ACTL1 is not conductive in an area overlapping the third gate electrode GE3. In an embodiment, the third transistor ST3 may have a top gate structure in which the third gate electrode GE3 is disposed above the third active area ACT3.

The third drain electrode DE3 and the third source electrode SE3 may be disposed in (or defined by portions of) the first active layer ACTL1. The third drain electrode DE3 and the third source electrode SE3 may be formed by heat treating and conducting the first active layer ACTL1. The third drain electrode DE3 and the third source electrode SE3 may be conductors of a P-type semiconductor or an N-type semiconductor, but are not limited thereto.

The third drain electrode DE3 may be electrically connected to the first source electrode SE1 of the first transistor ST1. In an embodiment, for example, the third drain electrode DE3 may be connected to the first source electrode SE1 of the first transistor ST1 through the third connection electrode CE3. Accordingly, the third drain electrode DE3 may supply the initialization voltage to the first source electrode SE1 of the first transistor ST1, and may receive the sensing voltage from the first source electrode SE1 of the first transistor ST1.

The third drain electrode DE3 may be connected to the first capacitor electrode CPE1 of the first capacitor C1. In an embodiment, for example, the third drain electrode DE3 may be connected to the first capacitor electrode CPE1 of the first capacitor C1 through the third connection electrode CE3, the first source electrode SE1 of the first transistor ST1, and the eighth electrode CE8.

The third source electrode SE3 may be connected to the initialization voltage line VIL. In an embodiment, for example, the third source electrode SE3 may be connected to the initialization voltage line VIL through the fourth connection electrode CE4. Accordingly, the third source electrode SE3 may receive the initialization voltage from the initialization voltage line VIL and supply the sensing voltage to the initialization voltage line VIL.

The first capacitor electrode CPE1 may be connected to the third drain electrode DE3 of the third transistor ST3 through the eighth connection electrode CE8, the first source electrode SE1 of the first transistor ST1, and the third connection electrode CE3.

The second capacitor electrode CPE2 may be connected to the second source electrode SE2 of the second transistor ST2 through the second connection electrode CE2 and the seventh connection electrode CE7.

In the display device 10 according to an embodiment, the second active area ACT2 of the second transistor ST2 and the third active area ACT3 of the third transistor ST3 may be disposed in (or defined by) different layers. In an embodiment, for example, the second active area ACT2 of the second transistor ST2 may be disposed in (or defined by a portion of) the second active layer ACTL2, and the third active area ACT3 of the third transistor ST3 may be disposed in (or defined by a portion of) the first active layer ACTL1.

In the display device 10 according to an embodiment, the second active area ACT2 of the second transistor ST2 and the third active area ACT3 of the third transistor ST3 may be positioned on opposite sides of each other with the second conductive layer MTL2 on which the auxiliary gate line BGL is disposed, interposed therebetween. In an embodiment, for example, the second active area ACT2 of the second transistor ST2 may be disposed on an upper layer of the second conductive layer MTL2, and the third active area ACT3 of the third transistor ST3 may be disposed on a lower layer of the second conductive layer MTL2. Accordingly, the second transistor ST2 may have a bottom gate structure, and the third transistor ST3 may have a top gate structure.

FIGS. 18 and 19 illustrate an embodiment where the second transistor ST2 of the display device 10 shown in FIGS. 9 and 10 is modified from the top gate structure to the bottom gate structure and the third transistor ST3 is modified from the bottom gate structure to the top gate structure as an example, but the disclosure is not limited thereto.

In another embodiment, for example, the second transistor ST2 of the display device 10 shown in FIGS. 11 and 12 may be modified to have a bottom gate structure, and the third transistor ST3 may have a top gate structure. In another embodiment, for example, the second transistor ST2 of the display device 10 shown in FIGS. 13 and 14 may be modified to have a bottom gate structure, and the third transistor ST3 may have a top gate structure. In another embodiment, for example, the second transistor ST2 of the display device 10 shown in FIGS. 15 and 16 may be modified to have a bottom gate structure, and the third transistor ST3 may have a top gate structure. In another embodiment, for example, the second transistor ST2 of the display device 10 shown in FIG. 17 may be modified to have a bottom gate structure, and the third transistor ST3 may have a top gate structure.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a light emitting element including a first electrode, a light emitting layer, and a second electrode;
a first transistor including a first source electrode, a first active area, a first drain electrode, and a first gate electrode;
a second transistor including a second source electrode, a second active area, a second drain electrode, and a second gate electrode; and
a third transistor including a third source electrode, a third active area, a third drain electrode, and a third gate electrode, wherein
the first source electrode is connected to the first electrode,
the second source electrode is connected to the first gate electrode,
the third drain electrode is connected to the first source electrode,
the second gate electrode and the third gate electrode are defined by a same conductive line, and
the second active area and the third active area are disposed in different layers.

2. The display device of claim 1, further comprising a gate line connected to the second gate electrode and the third gate electrode,
wherein the gate line applies a first gate voltage to the second gate electrode and a second gate voltage to the third gate electrode.

3. The display device of claim 2, wherein the same conductive line defining the second gate electrode and the third gate electrode is a portion of the gate line.

4. The display device of claim 2, wherein the first gate voltage and the second gate voltage are applied to the gate line at different timings.

5. The display device of claim 1, further comprising:
a first conductive layer in which the second gate electrode and the third gate electrode are disposed;
a first active layer disposed below the first conductive layer; and
a second active layer disposed above the first conductive layer,
wherein one of the second active area and the third active area is defined by a portion of the first active layer, and the other of the second active area and the third active area is defined by a portion of the second active layer.

6. The display device of claim 1, wherein one of the second transistor and the third transistor has a bottom gate structure, and the other of the second transistor and the third transistor has a top gate structure.

7. The display device of claim 1, wherein the second transistor and the third transistor are disposed to be spaced apart from each other in a plan view.

8. The display device of claim 1, wherein the second transistor and the third transistor are disposed to overlap each other in a plan view.

9. The display device of claim 8, wherein the second active area and the third active area are disposed to overlap each other in the plan view.

10. The display device of claim 8, wherein the second gate electrode and the third gate electrode are disposed to overlap each other in the plan view.

11. The display device of claim 8, wherein an extension direction of the second active area and an extension direction of the third active area are different from each other in the plan view.

12. A display device comprising:
a substrate;
a first active layer disposed on the substrate;
a first conductive layer disposed on the first active layer;
a second active layer disposed on the first conductive layer;
a second conductive layer disposed on the first conductive layer;
a light emitting element disposed on the second conductive layer;
a first transistor including a first source electrode, a first active area, a first drain electrode, and a first gate electrode;
a second transistor including a second source electrode, a second active area, a second drain electrode, and a second gate electrode; and
a third transistor including a third source electrode, a third active area, a third drain electrode, and a third gate electrode, wherein
the first gate electrode, the second gate electrode, and the third gate electrode are defined by portions of the first conductive layer, and
one of the second active area and the third active area is defined by a portion of the first active layer, and the other of the second active area and the third active area is defined by a portion of the second active layer.

13. The display device of claim 12, wherein the second transistor and the third transistor are disposed to be spaced apart from each other in a plan view.

14. The display device of claim 12, wherein the second transistor and the third transistor are disposed to overlap each other in a plan view.

15. The display device of claim 14, further comprising a third conductive layer disposed between the second conductive layer and the light emitting element, wherein
one of the second drain electrode and the third drain electrode is defined by a portion of the third conductive layer, and
one of the second source electrode and the third source electrode is defined by a portion of the third conductive layer.

16. The display device of claim 12, further comprising a first passivation film disposed on the second active layer,
wherein the first passivation film covers one of the second active area and the third active area in a plan view.

17. The display device of claim 16, further comprising a first connection electrode connecting the light emitting element and the first source electrode,
wherein the first connection electrode is defined by a portion of the second active layer.

18. The display device of claim 17, further comprising a first via film disposed on the first passivation film, wherein
the first connection electrode does not overlap the first passivation film in the plan view, and
the first via film covers the first connection electrode in the plan view.

19. An electronic device comprises a display device, the display device comprising:
a light emitting element including a first electrode, a light emitting layer, and a second electrode;
a first transistor including a first source electrode, a first active area, a first drain electrode, and a first gate electrode;
a second transistor including a second source electrode, a second active area, a second drain electrode, and a second gate electrode; and
a third transistor including a third source electrode, a third active area, a third drain electrode, and a third gate electrode, wherein
the first source electrode is connected to the first electrode,
the second source electrode is connected to the first gate electrode,
the third drain electrode is connected to the first source electrode,
the second gate electrode and the third gate electrode are defined by a same conductive line, and
the second active area and the third active area are disposed in different layers.

20. An electronic device comprises a display device, the display device comprising:
a substrate;
a first active layer disposed on the substrate;
a first conductive layer disposed on the first active layer;
a second active layer disposed on the first conductive layer;
a second conductive layer disposed on the first conductive layer;
a light emitting element disposed on the second conductive layer;
a first transistor including a first source electrode, a first active area, a first drain electrode, and a first gate electrode;
a second transistor including a second source electrode, a second active area, a second drain electrode, and a second gate electrode; and
a third transistor including a third source electrode, a third active area, a third drain electrode, and a third gate electrode, wherein
the first gate electrode, the second gate electrode, and the third gate electrode are defined by portions of the first conductive layer, and
one of the second active area and the third active area is defined by a portion of the first active layer, and the other of the second active area and the third active area is defined by a portion of the second active layer.
